(19) United States
(12) Patent Application Publication
(10) Pub. No.: US 2026/0334299 A1
(43) Pub. Date: Oct. 22, 2026

(54) SEMICONDUCTOR DEVICE

(71) Applicant: FUJI ELECTRIC CO., LTD., Kawasaki-shi (JP)

(72) Inventors: Taisuke FUKUDA, Matsumoto-city (JP); Hirohisa OYAMA, Matsumoto-city (JP)

(73) Assignee: FUJI ELECTRIC CO., LTD., Kawasaki-shi (JP)

(21) Appl. No.: 19/693,882

(22) Filed: Jun. 1, 2026

Related U.S. Application Data
(63) Continuation of application No. PCT/JP2025/016840, filed on May 8, 2025.

(30) Foreign Application Priority Data
Jun. 7, 2024 (JP) 2024-093077

(51) Int. Cl. H10W 76/12; H10W 40/20

(52) U.S. Cl. CPC H10W 76/12; H10W 40/235

(57) ABSTRACT

There is provided a semiconductor device capable of meeting various interface requirements. The semiconductor device includes semiconductor units having sealing resins sealing semiconductor chips, positive electrode parts and negative electrode parts extending from one side surface of the corresponding one of the sealing resins, output parts extending from the other side surface opposite to the corresponding one side surface, and a plurality of control units exposed from the sealing resins, first resin members arranged opposite to the corresponding one side surface and having insulating first walls arranged between the positive electrode parts and the negative electrode parts, second resin members arranged opposite to the other side surface, and third resin members, respectively, holding the plurality of control terminals respectively bonded to the control units.

### CROSS-REFERENCE TO RELATED APPLICATION

This application is a Continuation of PCT Application No. PCT/JP2025/016840, filed on May 8, 2025, and claims the priority of Japanese Patent Application No. 2024-093077, filed on Jun. 7, 2024, the contents of which are incorporated herein by reference.

### TECHNICAL FIELD

The present disclosure relates to a semiconductor device (power semiconductor module).

### BACKGROUND ART

To perform terminal bonding by soldering at a relatively low cost without forming a frame body using a heat-resistant resin, JP2017-022157A discloses, as a solution, a power semiconductor device including: a cooling unit; wiring patterns arranged on the cooling unit; switching elements and rectifying elements connected on the wiring patterns; plate-like leads having terminal parts and connection parts and connected to the switching elements and the rectifying elements via the connection parts; and a frame body which surrounds the wiring patterns, the switching elements, and the rectifying elements and to which the terminal parts are fixed, in which the frame body contains at least two divided bodies, and the divided bodies are inserted between the cooling unit and the plate-like leads from the lateral side of the wiring patterns.

JP2024-000071A discloses that, even when a shape change of a transfer molded power module is required, electrode terminals of the power module are separated from electrodes, and the separated electrode terminals are accurately post-attached to the electrodes, making it easy to change the electrode positions of the module.

WO2016/031462A1 discloses a power semiconductor module including: a cooling unit; a plurality of power semiconductor units aligned on and fixed to the cooling unit; and a bus bar unit electrically connecting the power semiconductor units, in which the power semiconductor units each include a stacked substrate obtained by sequentially stacking a circuit plate, an insulating plate, and a metal plate, a semiconductor element fixed to the circuit plate, a wiring member having a printed circuit board and a plurality of conductive posts, an external terminal electrically and mechanically connected to the circuit plate, and an insulating sealing material, and the bus bar unit includes a plurality of bus bars interconnecting the external terminals of the power semiconductor units.

JP2018-029141A discloses a semiconductor device including: a plurality of semiconductor units each including semiconductor elements, a unit casing sealing the semiconductor elements, and first unit terminals exposed in a first recessed part provided in the top surface of the unit casing; a first unit connecting part including first connecting terminals connected to the first unit terminals corresponding to the plurality of semiconductor units, first connecting conductors connecting the plurality of first connecting terminals, and first connecting-conductor sealing parts sealing the first connecting conductors and exposing the plurality of first connecting terminals; and a plurality of first recess sealing parts sealing connection parts between the first unit terminals and the first connecting terminals in the recess of the first recessed part, corresponding to the plurality of semiconductor units.

### SUMMARY OF INVENTION

### Technical Problem

A power semiconductor module is difficult to meet various interface requirements of customers and the like.

In view of the above-described problem, it is an object of the present disclosure to provide a semiconductor device capable of meeting various interface requirements.

One aspect of the present disclosure is a semiconductor device including: a semiconductor unit having a sealing resin configured to seal a semiconductor chip, a positive electrode part and a negative electrode part extending from one side surface of the sealing resin, an output part extending from another side surface opposite to the one side surface, and a plurality of control units exposed from the sealing resin; a first resin member arranged opposite to the one side surface and having an insulating first wall arranged between the positive electrode part and the negative electrode part; a second resin member arranged opposite to the other side surface; and a third resin member configured to hold a plurality of control terminals respectively bonded to the control units.

In the one aspect of the present disclosure, the semiconductor device may further include a cooling unit arranged on a bottom surface side of the semiconductor unit, wherein an insulation sheet may be provided, the insulation sheet being configured to cover a region facing at least the positive electrode part, the negative electrode part, and the output part of a top surface of the cooling unit in plan view and extending to a bottom surface of an outer edge of the semiconductor unit, a bottom surface side of the first resin member, and a bottom surface of the second resin member.

In the one aspect of the present disclosure, the third resin member may be arranged on the semiconductor unit and engaged with the first resin member and the second resin member.

In the one aspect of the present disclosure, one end of the control terminal may extend in a side surface direction of the third resin member.

In the one aspect of the present disclosure, in the semiconductor unit, one of the positive electrode part or the negative electrode part may have a width larger in a direction orthogonal to an extension direction of the positive electrode part and the negative electrode part than a width of another one of the positive electrode part or the negative electrode part, and the output part of the semiconductor unit may have a width in a direction orthogonal to an extension direction of the output part same as the width of one of the positive electrode part or the negative electrode part, and the second resin member may have a shape same as a shape of the first resin member.

In the one aspect of the present disclosure, the semiconductor unit may have a plurality of the positive electrode parts, the semiconductor device may further include: a positive electrode terminal held by the first resin member, having a fastening hole, and having a plurality of bonding parts connected to the positive electrode parts; and a negative electrode terminal held by the first resin member, having a fastening hole, and having a bonding part connected to the negative electrode part, wherein, the first resin member may have a second wall configured to separate the positive electrode terminal and the negative electrode terminal from each other.

In the one aspect of the present disclosure, the semiconductor device may further include an output terminal held by the second resin member, having a fastening hole, and connected to the output part.

In the one aspect of the present disclosure, the control unit may include a pin protruding from a top surface of the sealing resin.

In the one aspect of the present disclosure, the control unit may include a pad flush with a top surface of the sealing resin.

In the one aspect of the present disclosure, the semiconductor device may include a plurality of the semiconductor units arranged on the cooling unit, wherein the first resin member corresponding to each of the semiconductor unit may be integrally formed, and the second resin member corresponding to each of the semiconductor unit may be integrally formed.

Note that the summary of the invention does not describe all necessary features of the present disclosure. Subcombinations of these features can also be included in the invention.

### BRIEF DESCRIPTION OF DRAWINGS

FIG. 1 is a perspective view of a semiconductor device according to a first embodiment;

FIG. 2 is a top view of the semiconductor device according to the first embodiment;

FIG. 3 is a side view of the semiconductor device according to the first embodiment;

FIG. 4 is another side view of the semiconductor device according to the first embodiment;

FIG. 5 is a perspective view of a semiconductor unit according to the first embodiment;

FIG. 6 is a cross-sectional view of the semiconductor unit according to the first embodiment;

FIG. 7 is a perspective view of a control terminal unit according to the first embodiment;

FIG. 8 is a perspective view of the semiconductor unit and the control terminal unit according to the first embodiment;

FIG. 9 is another perspective view of the semiconductor unit and the control terminal unit according to the first embodiment;

FIG. 10 is a perspective view of the semiconductor unit and control terminals according to the first embodiment;

FIG. 11 is another perspective view of the semiconductor unit and the control terminals according to the first embodiment;

FIG. 12 is a perspective view of a positive and negative electrode terminal case according to the first embodiment;

FIG. 13 is a perspective view of an output terminal case according to the first embodiment;

FIG. 14 is a side view of a part of the semiconductor device according to the first embodiment;

FIG. 15 is another side view of the part of the semiconductor device according to the first embodiment;

FIG. 16 is still another side view of the part of the semiconductor device according to the first embodiment;

FIG. 17 is an exploded perspective view of the semiconductor device according to the first embodiment;

FIG. 18 is a perspective view of a positive and negative electrode terminal case according to a modification of the first embodiment;

FIG. 19 is a perspective view of an output terminal case according to the modification of the first embodiment;

FIG. 20 is a perspective view of a semiconductor device according to a second embodiment;

FIG. 21 is a top view of the semiconductor device according to the second embodiment;

FIG. 22 is a side view of the semiconductor device according to the second embodiment;

FIG. 23 is another side view of the semiconductor device according to the second embodiment;

FIG. 24 is another perspective view of the semiconductor device according to the second embodiment;

FIG. 25 is a top view of a control terminal unit according to the second embodiment;

FIG. 26 is a bottom view of the control terminal unit according to the second embodiment;

FIG. 27 is a bottom view of a semiconductor unit, a positive and negative electrode terminal unit, and an output terminal unit according to the second embodiment;

FIG. 28 is a top view of the positive and negative electrode terminal unit according to the second embodiment;

FIG. 29 is a bottom view of the positive and negative electrode terminal unit according to the second embodiment;

FIG. 30 is a top view of a positive electrode terminal and a negative electrode terminal according to the second embodiment;

FIG. 31 is a side view of a part of the semiconductor device according to the second embodiment;

FIG. 32 is a side view of a part of the semiconductor device according to the second embodiment;

FIG. 33 is a top view of an output terminal unit according to the second embodiment;

FIG. 34 is a bottom view of the output terminal unit according to the second embodiment;

FIG. 35 is an exploded perspective view of the semiconductor device according to the second embodiment; and

FIG. 36 is bottom view of a semiconductor unit, a positive and negative electrode terminal unit, and an output terminal unit according to a modification of the second embodiment.

### DESCRIPTION OF EMBODIMENTS

With reference to the drawings, the following describes first and second embodiments of the present disclosure.

In the drawings to be referred to in the following description, identical or similar parts have identical or similar reference signs.

It should be noted that the drawings are schematic, and the relationship between thickness and flat dimension, the ratio between layer thicknesses, and the like are different from actual ones. Accordingly, a specific thickness or dimension should be determined in consideration of the following description. Besides, it is needless to say that different drawings include parts with different dimensional relationships or ratios.

The definitions of directions such as “up”, “down”, “up-down”, “right”, “left”, “right-left”, and so on are merely definitions for convenience of the description and do not restrict the technical idea of the present disclosure. For example, when a target is rotated by 90° and observed, the “up-down direction” is replaced with the “right-left direction”, and when the target is rotated by 180° and observed, the top and bottom are upside down.

A “top surface” and a “bottom surface” may be replaced with a “front surface” and a “back surface”, respectively. Besides, a “first main surface” and a “second main surface” of each member are main surfaces opposed to each other, and when the “first main surface” is a top surface, the “second main surface” is a bottom surface, for example. In addition, the “first main surface” and the “second main surface” may be read as “one main surface” and “the other main surface”, respectively.

### First Embodiment

### Structure of Semiconductor Device

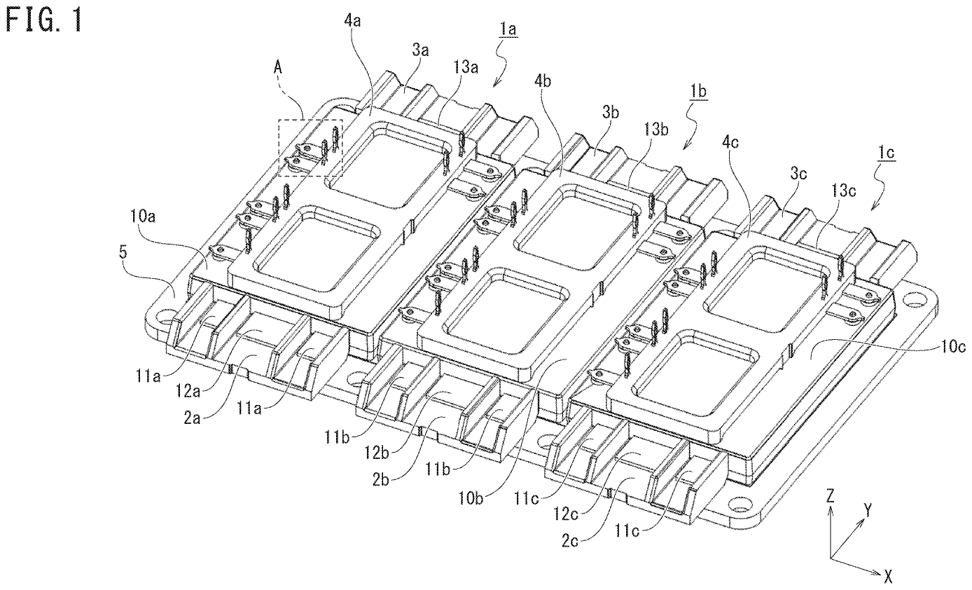

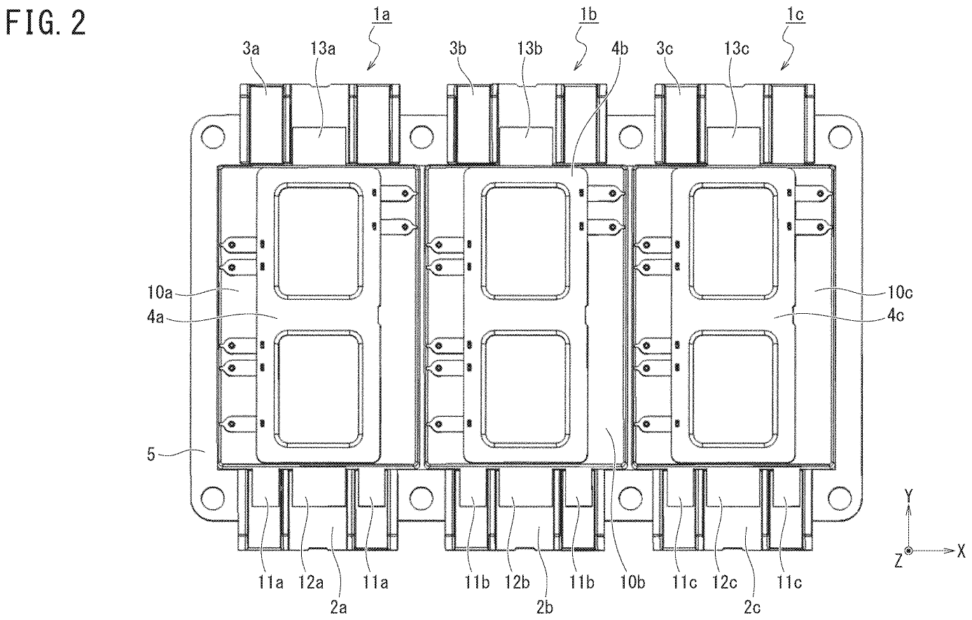

As a semiconductor device according to a first embodiment, a 6-in-1 power semiconductor module is described as an example. FIG. 1 is a perspective view of a semiconductor device according to the first embodiment. FIG. 2 is a top view of the semiconductor device according to the first embodiment. As illustrated in FIGS. 1 and 2, the semiconductor device according to the first embodiment includes a plurality (three) of semiconductor units 1a to 1c. Each of the plurality of semiconductor units 1a to 1c is a 2-in-1 module for one phase, and the semiconductor units 1a to 1c for three phases are provided to be aligned in one direction.

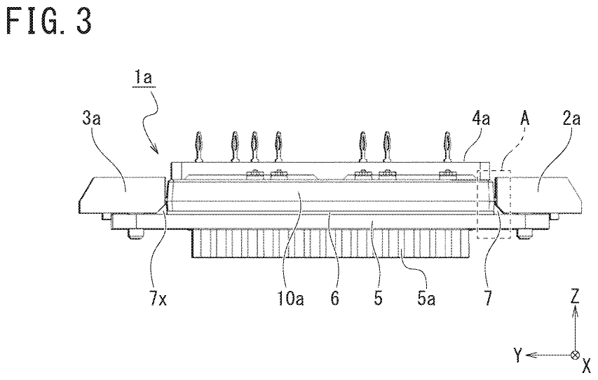

In FIGS. 1 and 2, a direction in which the plurality of semiconductor units 1a to 1c is aligned (right and left direction in FIG. 2) is defined as the X-axis direction, and one direction in the X-axis direction (rightward in FIG. 2) is defined as the positive direction. A direction orthogonal to the X-axis direction (up and down direction in FIG. 2) is defined as the Y-axis direction, and one direction in the Y-axis (upward direction in FIG. 2) is defined as the positive direction. A direction orthogonal to the X-axis direction and the Y-axis direction (forward and depth direction in FIG. 2) is defined as the Z-axis direction, and the upward side of the plurality of semiconductor units 1a to 1c (forward direction in FIG. 2) is defined as the positive direction of the Z-axis. The definitions of the directions and the orientations illustrated in FIG. 3 and subsequent figures are the same as those in the FIGS. 1 and 2.

As illustrated in FIGS. 1 and 2, the plurality of semiconductor units 1a to 1c is provided on the top surface side of a cooling unit 5. The cooling unit 5 contains a conductive material, such as copper (Cu), a Cu alloy, aluminum (Al), or an Al alloy, for example.

On the top surface side of the cooling unit 5, terminal cases (also referred to as “positive and negative electrode terminal cases”) 2a to 2c which are resin members (insulation members) and terminal cases (also referred to as “output terminal cases”) 3a to 3c which are resin members (insulation members) are provided to sandwich the plurality of semiconductor units 1a to 1c in a direction orthogonal to the direction in which the plurality of semiconductor units 1a to 1c is aligned (Y-axis direction). The positive and negative electrode terminal cases 2a to 2c and the output terminal cases 3a to 3c contain resin materials, such as polyphenylene sulfide (PPS). On the top surface side of the plurality of semiconductor units 1a to 1c, a plurality of control terminal units 4a to 4c is provided.

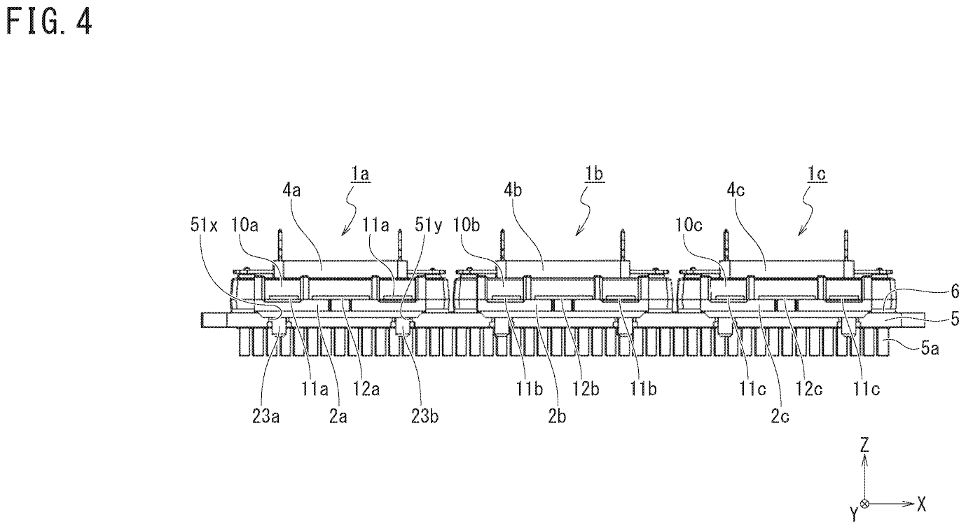

FIG. 3 is a side view of the semiconductor device according to the first embodiment as viewed from the positive direction of the X-axis direction. FIG. 4 is a side view of the semiconductor device according to the first embodiment as viewed from the positive direction of the Y-axis direction. As illustrated in FIGS. 3 and 4, cooling fins 5a are provided on the bottom surface side of the cooling unit 5. The cooling fins 5a do not have to be provided on the bottom surface side of the cooling unit 5. Between the cooling unit 5 and the plurality of semiconductor units 1a to 1c, a heat dissipation member 6 is provided. The heat dissipation member 6 contains a thermal interface material (TIM) or the like, for example.

As illustrated in FIG. 4, protruding parts 23a, 23b are provided on the bottom surface side of the positive and negative electrode terminal case 2a. The protruding parts 23a, 23b are engaged in (fitted into) recessed parts (notched parts) 51x, 51y provided in the cooling unit 5, facilitating the assembly. The positive and negative electrode terminal cases 2b, 2c also have the same configuration as that of the positive and negative electrode terminal case 2a.

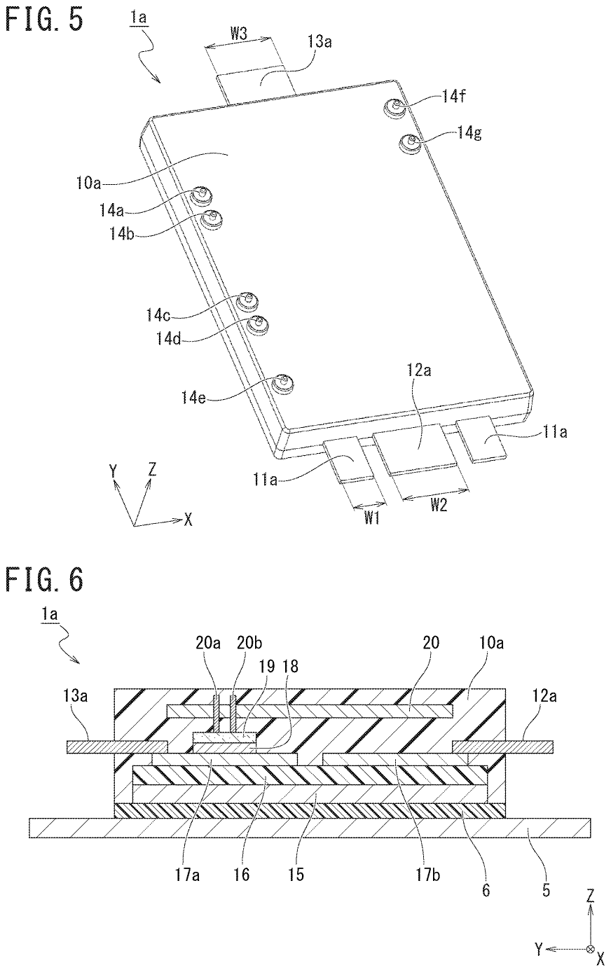

FIG. 5 is a perspective view of the semiconductor unit 1a. The semiconductor unit 1a includes a sealing resin 10a having a substantially rectangular parallelepiped shape, and a plurality (pair) of positive electrode parts 11a which are conductive parts, a negative electrode part 12a which is a conductive part, an output part 13a which is a conductive part, and a plurality of control units 14a to 14g which is a conductive part, each of which protrudes from the side surfaces of the sealing resin 10a.

In the sealing resin 10a, the direction in which the plurality of semiconductor units 1a to 1c is aligned (X-axis direction) is defined as the transverse direction, and the direction orthogonal to the direction in which the plurality of semiconductor units 1a to 1c is aligned (Y-axis direction) is defined as the longitudinal direction. The sealing resin 10a is formed integrally with the pair of positive electrode parts 11a, the negative electrode part 12a, the output part 13a, and the plurality of control units 14a to 14g by transfer molding or the like. The sealing resin 10a contains an insulating resin material, such as epoxy resin, for example. Inside the sealing resin 10a, a semiconductor chip is provided.

The pair of positive electrode parts 11a, the negative electrode part 12a, the output part 13a, and the plurality of control units 14a to 14g are electrically connected to the semiconductor chip inside the sealing resin 10a. The pair of positive electrode parts 11a, the negative electrode part 12a, the output part 13a, and the plurality of control units 14a to 14g contain a conductive material, such as copper (Cu), a Cu alloy, aluminum (Al), or an Al alloy, for example.

The pair of positive electrode parts 11a protrudes from one side surface in the longitudinal direction (Y-axis direction) of the sealing resin 10a and extends in the longitudinal direction (Y-axis direction) of the sealing resin 10a. In the semiconductor device according to the first embodiment, the pair of positive electrode parts 11a constitutes a positive electrode terminal (also referred to as “main terminal” or “external connection terminal”) connectable to an external member, such as a capacitor, by laser welding or the like. The pair of positive electrode parts 11a may be provided with a fastening hole (through hole) which allows screw fastening to the external member.

The negative electrode part 12a protrudes from the same side surface as the side surface from which the pair of positive electrode parts 11a protrudes of the sealing resin 10a and extends in the longitudinal direction (Y-axis direction) of the sealing resin 10a. The negative electrode part 12a is provided at a position sandwiched between the pair of positive electrode parts 11a and is separated from the pair of positive electrode parts 11a. In a direction orthogonal to the extension direction of the pair of positive electrode parts 11a and the negative electrode part 12a (X-axis direction), a width W2 of the negative electrode part 12a is larger than a width W1 of the pair of positive electrode parts 11a. In the semiconductor device according to the first embodiment, the negative electrode part 12a constitutes a negative electrode terminal (also referred to as “main terminal” or “external connection terminal”) connectable to an external member, such as a capacitor, by laser welding or the like. The negative electrode part 12a may be provided with a fastening hole (through hole) which allows screw fastening to the external member.

The output part 13a protrudes from the side surface on the side opposite to the side surface from which the pair of positive electrode parts 11a and the negative electrode part 12a protrude of the sealing resin 10a and extends in the longitudinal direction (Y-axis direction) of the sealing resin 10a. In the direction orthogonal to the extension direction of the output part 13a (X-axis direction), a width W3 of the output part 13a is larger than the width W1 of the pair of positive electrode parts 11a and is substantially the same as the width W2 of the negative electrode part 12a. In the semiconductor device according to the first embodiment, the output part 13a constitutes an output terminal (also referred to as “main terminal” or “external connection terminal”) connectable to an external member, such as a motor, by laser welding. The output part 13a may be provided with a fastening hole (through hole) which allows screw fastening to the external member.

The plurality of control units 14a to 14g is exposed and protrudes from the top surface side of the sealing resin 10a. The plurality of control units 14a to 14g may be exposed flush with the top surface of the sealing resin 10a without protruding from the top surface of the sealing resin 10a. Among the plurality of control units 14a to 14g, the control units 14a to 14e are provided along one side in the longitudinal direction (Y-axis direction) of the sealing resin 10a, and the control units 14f and 14g are provided along the other side in the longitudinal direction (Y-axis direction) of the sealing resin 10a. The number and the arrangement positions of the plurality of control units 14a to 14g are not particularly limited.

FIG. 6 is a schematic cross-sectional view of the cooling unit 5, the heat dissipation member 6, and the semiconductor unit 1a cut along a cross-section along the longitudinal direction (Y-axis direction) of the sealing resin 10a passing through the negative electrode part 12a and the output part 13a of the semiconductor unit 1a. The semiconductor unit 1a includes a metal plate 15 provided on the top surface side of the heat dissipation member 6, an insulation layer 16 provided on the top surface side of the metal plate 15, and conductive layers 17a, 17b provided on the top surface side of the insulation layer 16. The metal plate 15, the insulation layer 16, and the conductive layers 17a, 17b may be constituted by insulation circuit boards, such as direct copper bond (DCB) boards or active metal brazing (AMB) boards.

The metal plate 15 contains a conductive material, such as copper (Cu), a Cu alloy, aluminum (Al), or an Al alloy, for example. The insulation layer 16 contains a resin insulation material, such as polyphenylene sulfide (PPS) or a liquid crystal polymer (LCP), or a ceramic material containing oxide aluminum (Al₂O₃), nitride aluminum (AlN), silicon nitride (Si₃N₄), boron nitride (BN), or the like as the main agent, for example.

The conductive layers 17a, 17b contain a conductive material, such as copper (Cu), a Cu alloy, aluminum (Al), or an Al alloy, for example. One end of the output part 13a is connected to the top surface side of the conductive layer 17a by laser welding or the like. One end of the negative electrode part 12a is connected to the top surface side of the conductive layer 17b by laser welding or the like. The number and the arrangement positions of the conductive layers 17a, 17b are not particularly limited.

The semiconductor unit 1a further includes a semiconductor chip 19 provided on the top surface side of the conductive layer 17a by a bonding material 18, such as solder or a sintered material, a wiring board (printed circuit board) 20 provided above the semiconductor chip 19, and the sealing resin 10a sealing the semiconductor chip 19, the printed circuit board 20, and the like.

The semiconductor chip 19 contains a semiconductor, such as silicon (Si), silicon carbide (SiC), gallium nitride (GaN), gallium oxide (Ga₂O₃), or diamond (C), for example. The semiconductor chip 19 may be a field effect transistor (FET), such as a metal oxide semiconductor field effect transistor (MOSFET), an insulated gate bipolar transistor (IGBT), a reverse conducting insulated gate bipolar transistor (RC-IGBT) in which a diode is connected in inverse parallel to an IGBT, a static induction (SI) thyristor, a gate turn-off (GTO) thyristor, or the like. The type, the number, and the arrangement position of the semiconductor chip 19 are not particularly limited. Herein, as one example, the semiconductor chip 19 constitutes an IGBT having a collector electrode on the bottom surface side and an emitter electrode and a gate electrode on the top surface side.

The semiconductor chip 19 is electrically connected to the printed circuit board 20 via pin-like connection members (pins) 20a, 20b. The connection members 20a, 20b are press-fitted into the printed circuit board 20. The printed circuit board 20 may be a multilayer wiring board having a plurality of conductive layers via an insulation layer. To the printed circuit board 20, the control units 14a to 14g illustrated in FIG. 5 are electrically connected. The control units 14a to 14g are electrically connected to a gate electrode and the like of the semiconductor chip 19 via the printed circuit board 20. The semiconductor chip 19 and the printed circuit board 20 may be bonded with a bonding material, such as solder or a sintered material, or may be bonded via a connection member, such as a copper block or a bump, in place of the pin.

The semiconductor units 1b, 1c illustrated in FIGS. 1 to 4 have the same configuration as that of the semiconductor unit 1a illustrated in FIGS. 5 and 6. The semiconductor unit 1b includes a sealing resin 10b, and a pair of positive electrode parts 11b, a negative electrode part 12b, and an output part 13b protruding from the side surfaces of the sealing resin 10b. The semiconductor unit 1c includes a sealing resin 10c, and a pair of positive electrode parts 11c, a negative electrode part 12c, and an output part 13c protruding from the side surfaces of the sealing resin 10c.

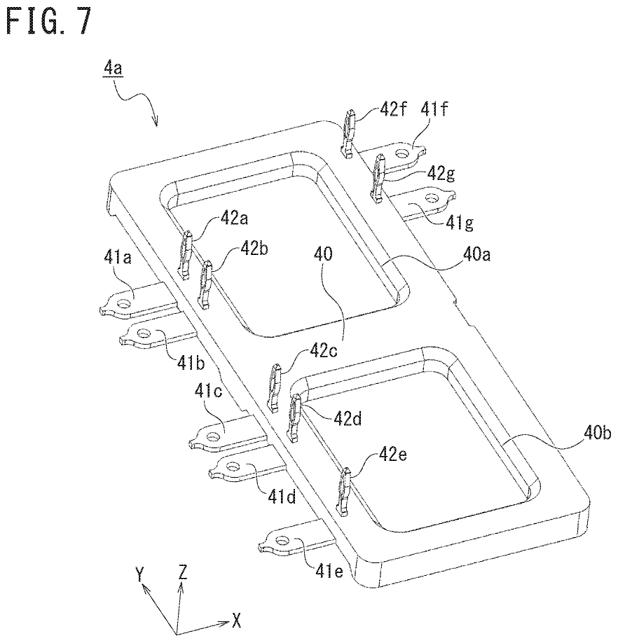

FIG. 7 is a perspective view of the control terminal unit 4a. The control terminal unit 4a includes a terminal holding part 40 which is a resin member (insulation member), and a plurality of control terminals (41a, 42a), (41b, 42b), (41c, 42c), (41d, 42d), (41e, 42e), (41f, 42f), (41g, 42g) held by the terminal holding part 40. The terminal holding part 40 is formed integrally with the control terminals (41a, 42a), (41b, 42b), (41c, 42c), (41d, 42d), (41e, 42e), (41f, 42f), (41g, 42g) by transfer molding or the like.

The terminal holding part 40 contains an insulating resin material, such as epoxy resin, for example. The terminal holding part 40 has an outer shape of a substantially rectangular parallelepiped shape and has a figure-eight planar pattern provided with opening parts 40a, 40b. The terminal holding part 40 includes two striped extension parts extending in the longitudinal direction (Y-axis direction) and three striped connection parts extending in the transverse direction (X-axis direction) and connecting the two extension parts in plan view.

The plurality of control terminals (41a, 42a), (41b, 42b), (41c, 42c), (41d, 42d), (41e, 42e), (41f, 42f), (41g, 42g) contain a conductive material, such as copper (Cu), a Cu alloy, aluminum (Al), or an Al alloy, for example. The plurality of control terminals (41a, 42a), (41b, 42b), (41c, 42c), (41d, 42d), (41e, 42e), (41f, 42f), (41g, 42g) is provided at a position corresponding to the plurality of control units 14a to 14g of the semiconductor unit 1a illustrated in FIG. 5 and is electrically connected to the plurality of control units 14a to 14g. The control terminals (41a, 42a), (41b, 42b), (41c, 42c), (41d, 42d), (41e, 42e) are provided in one of the two extension parts of the terminal holding part 40. The control terminals (41f, 42f), (41g, 42g) are provided in the other one of the two extension parts of the terminal holding part 40.

The control terminals (41a, 42a), (41b, 42b), (41c, 42c), (41d, 42d), (41e, 42e), (41f, 42f), (41g, 42g) contain bonding parts 41a to 41g protruding from the side surfaces of the terminal holding part 40 and the terminal parts 42a to 42g connected to the bonding parts 41a to 41g, respectively, inside the terminal holding part 40 and protruding from the top surface of the terminal holding part 40. The bonding parts 41a to 41g and the terminal parts 42a to 42g may be integrally formed.

The bonding parts 41a to 41g protrude from the side surfaces along the longitudinal direction (Y-axis direction) of the terminal holding part 40 and extend in the transverse direction (X-axis direction) which is the side surface direction of the terminal holding part 40. The bonding parts 41a to 41g may protrude from the bottom surfaces of the terminal holding part 40, instead of the side surface of the terminal holding part 40, bend in an L-shape, and extend in the transverse direction (X-axis direction) of the terminal holding part 40. The bonding parts 41a to 41g may be bent into an L-shape after transfer molding with the terminal holding part 40. The bonding parts 41a to 41g are bonded to be electrically connected to the control units 14a to 14g of the semiconductor unit 1a illustrated in FIG. 5 by laser welding or the like.

The terminal parts 42a to 42g protrude from the top surface of the terminal holding part 40 and extend upward (positive direction of the Z-axis direction). The terminal parts 42a to 42g can be connected to an external member, such as a control circuit board. More specifically, the control terminals (41a, 42a), (41b, 42b), (41c, 42c), (41d, 42d), (41e, 42e) function as external connection terminals connectable to the external member. Herein, a case in which the terminal parts 42a to 42g have a press-fit terminal shape is described as an example, but the shape of the terminal parts 42a to 42g is not particularly limited. The terminal parts 42a to 42g may have a pin shape, a rod shape, a cylindrical shape, or a polygonal columnar shape, or the like, for example.

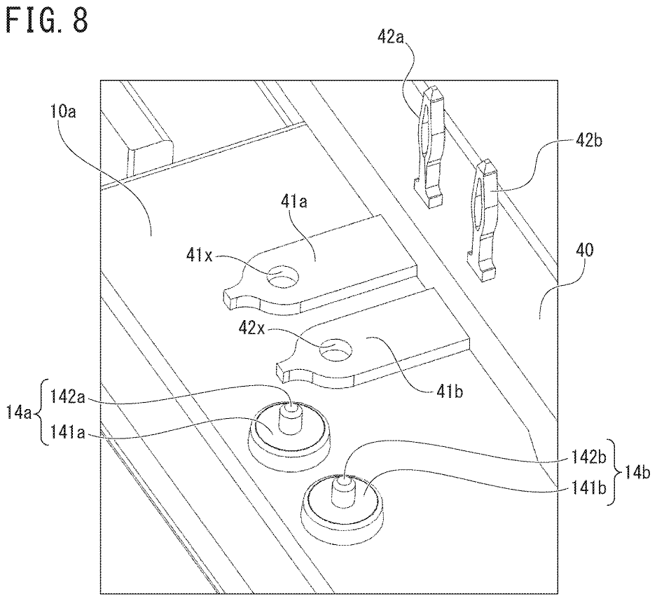

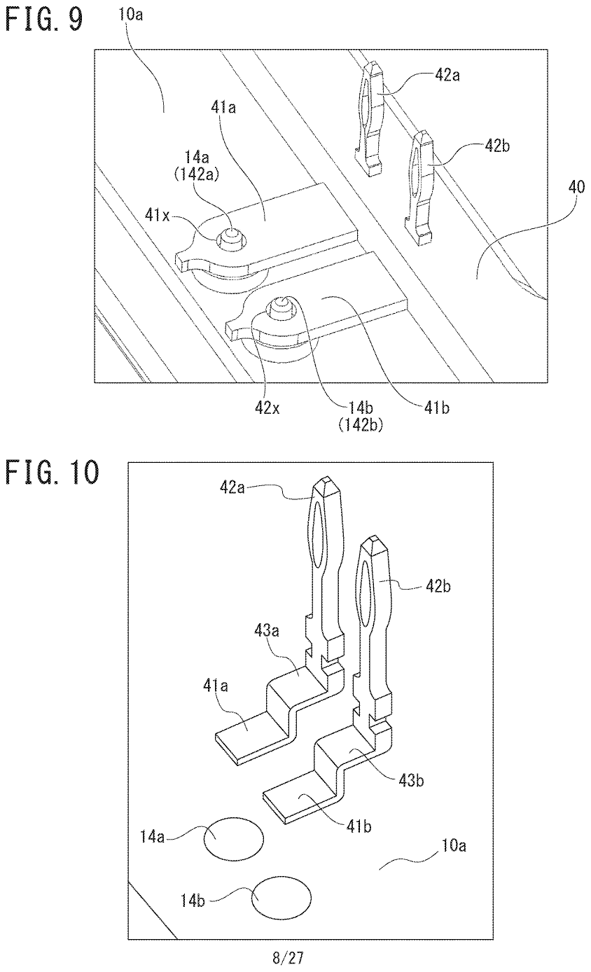

FIG. 8 is a perspective view of the control units 14a, 14b exposed on the top surface of the sealing resin 10a of the semiconductor unit 1a and the control terminals (41a, 42a), (41b, 42b) of the control terminal unit 4a before the semiconductor unit 1a and the control terminal unit 4a are assembled together. FIG. 9 is a perspective view of the control units 14a, 14b exposed on the top surface of the sealing resin 10a of the semiconductor unit 1a and the control terminals (41a, 42a), (41b, 42b) of the control terminal unit 4a after the semiconductor unit 1a and the control terminal unit 4a are assembled together.

As illustrated in FIG. 8, the control unit 14a includes a pad (land) 141a exposed from the top surface of the sealing resin 10a and having a circular planar pattern and a pin 142a protruding from the top surface of the pad 141a. The control unit 14b includes a pad (land) 141b exposed from the top surface of the sealing resin 10a and having a circular planar pattern and a pin 142b protruding from the top surface of the pad 141b. The control units 14a, 14b do not have to have the pads 141a, 141b, respectively, and may contain only the pins 142a, 142b, respectively, protruding from the top surface of the sealing resin 10a. The bonding parts 41a, 41b have a flat plate shape to be bonded to the pads 141a, 141b, respectively. The bonding parts 41a, 41b are provided with holes 41x, 42x, respectively.

As illustrated in FIG. 9, when the semiconductor unit 1a and the control terminal unit 4a are assembled together, the pins 142a, 142b of the control units 14a, 14b are engaged in (fitted into) the holes 41x, 42x of the bonding parts 41a, 41b, respectively, facilitating the assembly. Then, the control units 14a, 14b and the bonding parts 41a, 41b are bonded to each other, respectively, by laser welding or the like. Bonding portions of the control units 14c to 14g illustrated in FIG. 5 and the control terminals (41c, 42c), (41d, 42d), (41e, 42e), (41f, 42f), (41g, 42g), respectively, illustrated in FIG. 7 also have the same configuration as those of the bonding portions of the control units 14a, 14b and the control terminals (41a, 42a), (41b, 42b), respectively, illustrated in FIG. 9.

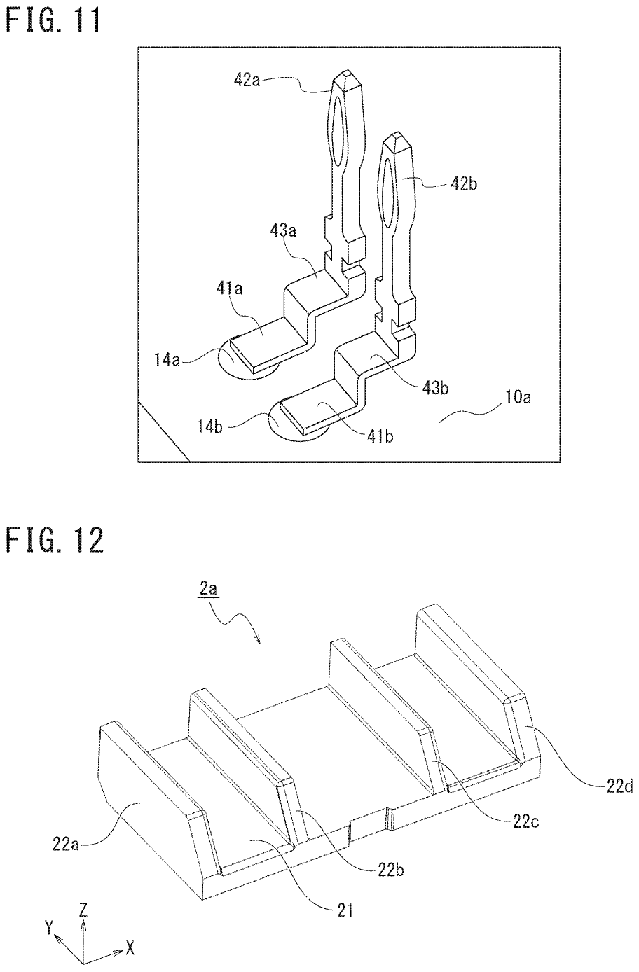

FIGS. 10 and 11 are perspective views illustrating modifications of the control units 14a, 14b exposed on the top surface of the sealing resin 10a of the semiconductor unit 1a and the control terminals (41a, 42a, 43a), (41b, 42b, 43b), respectively, of the control terminal unit 4a illustrated in FIGS. 8 and 9. FIG. 10 illustrates a state before the semiconductor unit 1a and the control terminal unit 4a are assembled together. FIG. 11 illustrates a state after the semiconductor unit 1a and the control terminal unit 4a are assembled together. FIGS. 10 and 11 do not illustrate the terminal holding part 40 holding the control terminals (41a, 42a, 43a), (41b, 42b, 43b).

As illustrated in FIG. 10, the control units 14a, 14b contain pads having a circular planar pattern exposed flush with the top surface of the sealing resin 10a, and pins are not provided on the top surfaces of the pads. The control terminals (41a, 42a, 43a) include the intermediate part 43a held inside the terminal holding part 40 between the bonding part 41a and the terminal part 42a and having a bent shape. The control terminals (41b, 42b, 43b) include the intermediate part 43b held inside the terminal holding part 40 between the bonding part 41b and the terminal part 42b and having a bent shape. The bonding parts 41a, 41b have a flat plate shape to be bonded to the control units 14a, 14b, respectively. The bonding parts 41a, 41b are not provided with holes.

As illustrated in FIG. 11, when the semiconductor unit 1a and the control terminal unit 4a are assembled together, the bonding parts 41a, 41b are positioned on the top surface of the control units 14a, 14b, respectively. Then, the control units 14a, 14b and the bonding parts 41a, 41b are bonded to each other, respectively, by laser welding or the like.

FIG. 12 is a perspective view of the positive and negative electrode terminal case 2a. The positive and negative electrode terminal case 2a houses the pair of positive electrode parts 11a and the negative electrode part 12a of the semiconductor unit 1a illustrated in FIG. 5 and has the function of ensuring the insulation distance including the creepage distance and the spatial distance between the pair of positive electrode parts 11a and the negative electrode part 12a and between the pair of positive electrode parts 11a and the negative electrode part 12a, and the cooling unit 5.

As illustrated in FIG. 12, the positive and negative electrode terminal case 2a includes a base plate 21 and walls 22a to 22d protruding from the top surface of the base plate 21 and extending upward. The walls 22a to 22d extend parallel to each other in the extension direction (Y-axis direction) of the pair of positive electrode parts 11a and the negative electrode part 12a of the semiconductor unit 1a illustrated in FIG. 5. The space between the walls 22a, 22b and the space between the walls 22c, 22d are substantially identical to each other and narrower than the space between the walls 22b, 22c. One of the pair of positive electrode parts 11a of the semiconductor unit 1a is housed in the space surrounded by the base plate 21 and the walls 22a, 22b. The negative electrode part 12a of the semiconductor unit 1a is housed in the space surrounded by the base plate 21 and the walls 22b, 22c. The other one of the pair of positive electrode parts 11a of the semiconductor unit 1a is housed in the space surrounded by the base plate 21 and the walls 22c, 22d. The positive and negative electrode terminal cases 2b, 2c illustrated in FIGS. 1 to 4 also have the same configuration as that of the positive and negative electrode terminal case 2a illustrated in FIG. 12.

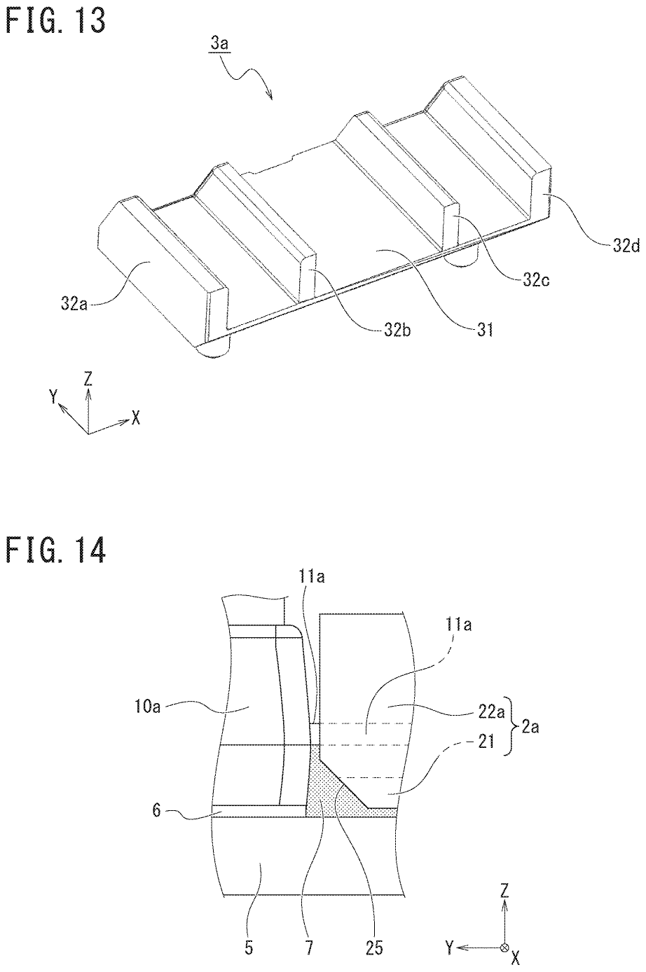

FIG. 13 is a perspective view of an output terminal case 3a. The output terminal case 3a houses the output part 13a of the semiconductor unit 1a illustrated in FIG. 5 and has the function of ensuring the insulation distance including the creepage distance and the spatial distance between the output part 13a and the cooling unit 5.

The output terminal case 3a illustrated in FIG. 13 has a viewpoint position different from that of the positive and negative electrode terminal case 2a illustrated in FIG. 12, but has substantially the same shape as that of the positive and negative electrode terminal case 2a. The output terminal case 3a includes a base plate 31 and walls 32a to 32d protruding from the top surface of the base plate 31 and extending upward. The output part 13a of the semiconductor unit 1a is housed in the space surrounded by the base plate 31 and the walls 32b, 32c. The output terminal cases 3b, 3c illustrated in FIGS. 1 to 4 also have the same configuration as that of the output terminal case 3a illustrated in FIG. 13. The output terminal case 3a may have a shape different from that of the positive and negative electrode terminal case 2a. For example, the output terminal case 3a may contain only a part housing the output part 13a of the base plate 31 and the walls 32b, 32c, and does not have to have the other parts of the base plate 31 and the walls 32a, 32d.

FIG. 14 is a side view of a connection portion between the semiconductor unit 1a and the positive and negative electrode terminal case 2a, in which a region A enclosed by the dashed line of FIG. 3 is enlarged. In FIG. 14, the positive and negative electrode terminal case 2a is separated from the sealing resin 10a, but the positive and negative electrode terminal case 2a may be in contact with the sealing resin 10a. The positive and negative electrode terminal case 2a has a tapered portion 25 in a lower part of an end part. The end part of the positive and negative electrode terminal case 2a does not have to have the tapered portion 25. The bottom surface of the positive electrode part 11a at a position where the base plate 21 of the positive and negative electrode terminal case 2a and the sealing resin 10a are separated from each other is opposite to the top surface of the cooling unit 5 without interposing the positive and negative electrode terminal case 2a therebetween.

The positive electrode part 11a protruding from the side surface of the sealing resin 10a is housed in the positive and negative electrode terminal case 2a. Although FIG. 14 illustrates an example in which the positive electrode part 11a is separated from the base plate 21 of the positive and negative electrode terminal case 2a, the positive electrode part 11a may be in contact with the base plate 21 of the positive and negative electrode terminal case 2a.

An insulating adhesive 7 is filled into the space surrounded by the top surface of the cooling unit 5, the heat dissipation member 6, the sealing resin 10a, the positive electrode part 11a, and the positive and negative electrode terminal case 2a to attach the members to each other. As the insulating adhesive 7, an epoxy resin adhesive or the like can be used. The insulating adhesive 7 has viscosity of about 5000 mPa·s (25 °C) or more, for example. The insulating adhesive 7 can ensure the insulation distance including the creepage distances and the spatial distance between the positive electrode part 11a and the cooling unit 5. The insulating adhesive 7 may enter between the bottom surface of the sealing resin 10a and the cooling unit 5. The insulating adhesive 7 may enter between the base plate 21 of the positive and negative electrode terminal case 2a and the cooling unit 5. The insulating adhesive 7 may enter between the positive electrode part 11a housed in the positive and negative electrode terminal case 2a and the base plate 21.

Although not illustrated in the figure, the insulating adhesive 7 is also filled into the space surrounded by the top surface of the cooling unit 5, the heat dissipation member 6, the sealing resin 10a, the negative electrode part 12a, and the positive and negative electrode terminal case 2a to attach the members to each other. More specifically, the insulating adhesive 7 covers a region facing at least the positive electrode part 11a and the negative electrode part 12a of the top surface of the cooling unit 5 in plan view. The insulating adhesive 7 can ensure the insulation distance between the negative electrode part 12a and the cooling unit 5. The insulating adhesive 7 may enter between the negative electrode part 12a housed in the positive and negative electrode terminal case 2a and the base plate 21.

The insulating adhesive 7 is also provided in the space surrounded by the top surface of the cooling unit 5, the heat dissipation member 6, the sealing resin 10b, the positive electrode part 11b, the negative electrode part 12b, and the positive and negative electrode terminal case 2b and in the space surrounded by the top surface of the cooling unit 5, the heat dissipation member 6, the sealing resin 10c, the positive electrode part 11c, the negative electrode part 12c, and the positive and negative electrode terminal case 2c to attach the members to each other. The insulating adhesive 7 can ensure the insulation distance between the positive electrode parts 11b, 11c and the negative electrode parts 12b, 12c, respectively, and the cooling unit 5.

As illustrated in FIG. 3, an insulating adhesive 7x similar to the insulating adhesive 7 is also provided in the space surrounded by the top surface of the cooling unit 5, the heat dissipation member 6, the sealing resin 10a, the output part 13a, and the output terminal case 3a to attach the members to each other. The insulating adhesive 7x can ensure the insulation distance between the output part 13a and the cooling unit 5. Although not illustrated in the figure, the insulating adhesive 7x is also provided in the space surrounded by the top surface of the cooling unit 5, the heat dissipation member 6, the sealing resin 10b, the output part 13b, and the output terminal case 3b and in the space surrounded by the top surface of the cooling unit 5, the heat dissipation member 6, the sealing resin 10c, the output part 13c, and the output terminal case 3c to attach the members to each other. The insulating adhesive 7x can ensure the insulation distance between the output parts 13b, 13c and the cooling unit 5.

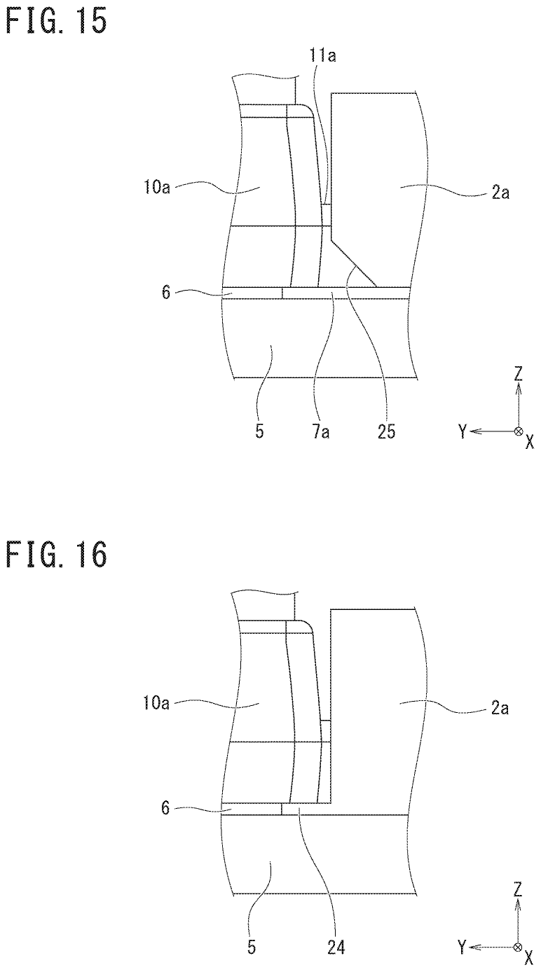

FIG. 15 is a modification of FIG. 14, and a side view of a connection portion between the semiconductor unit 1a and the positive and negative electrode terminal case 2a as in FIG. 14. In place of the insulating adhesive 7 illustrated in FIG. 14, an insulation sheet 7a which is a sheet-like (plate-like) insulation member is provided at a position opposite to the positive electrode part 11a on the top surface side of the cooling unit 5 as illustrated in FIG. 15. The insulation sheet 7a may extend to the bottom surface of the outer edge of the sealing resin 10a. The insulation sheet 7a may extend to the bottom surface of the positive and negative electrode terminal case 2a. As the insulation sheet 7a, an insulation material, such as insulation paper, polyimide or polyamide, epoxy resin, or polyphenylene sulfide (PPS) resin, can be used. The insulation sheet 7a can ensure the insulation distance between the positive electrode part 11a and the cooling unit 5.

Although not illustrated in the figure, the insulation sheet 7a is also provided to extend at a position opposite to the negative electrode part 12a on the top surface side of the cooling unit 5. More specifically, the insulation sheet 7a covers a region facing at least the positive electrode part 11a and the negative electrode part 12a of the top surface of the cooling unit 5 in plan view and extends to the bottom surface of the outer edge of the semiconductor unit 1a and the bottom surface of the positive and negative electrode terminal case 2a. The insulation sheet 7a can ensure the insulation distance between the negative electrode part 12a and the cooling unit 5. The insulation sheet 7a is further provided to extend at a position opposite to the positive electrode parts 11b, 11c and the negative electrode parts 12b, 12c, respectively, on the top surface side of the cooling unit 5. The insulation sheet 7a can ensure the insulation distance between the positive electrode parts 11b, 11c and the negative electrode parts 12b, 12c, respectively, and the cooling unit 5.

An insulation sheet 7b (see FIG. 17) similar to the insulation sheet 7a is also provided at a position opposite to the output parts 13a to 13c on the top surface side of the cooling unit 5. The insulation sheet 7b covers a region facing at least the output parts 13a to 13c of the top surface of the cooling unit 5 in plan view and extends to the bottom surfaces of the outer edges of the semiconductor units 1a to 1c and the bottom surfaces of the output terminal cases 3a to 3c, respectively. The insulation sheet 7b can ensure the insulation distance between the output parts 13a to 13c and the cooling unit 5.

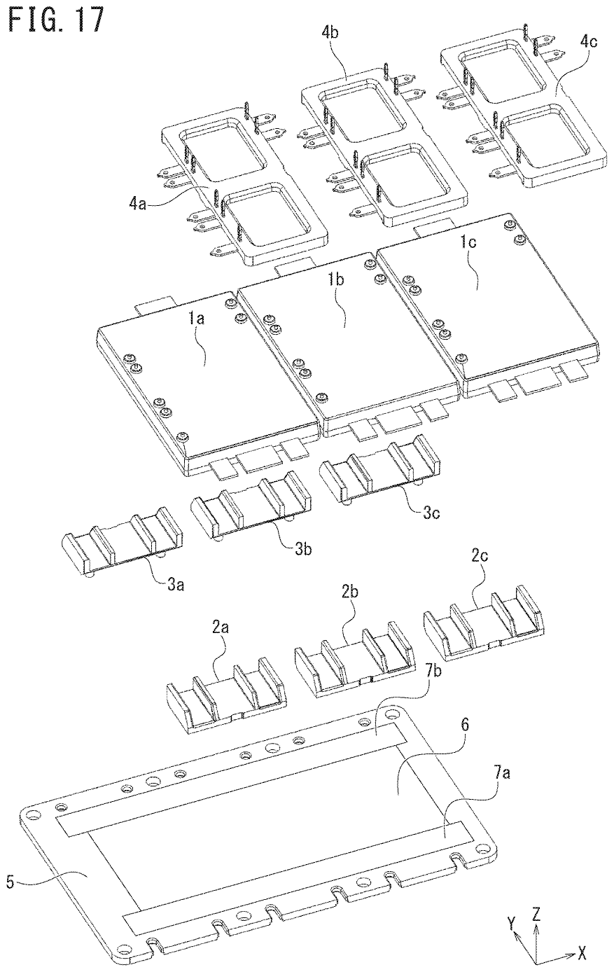

FIG. 16 is a further modification of FIG. 14, and is a side view of a connection portion between the semiconductor unit 1a and the positive and negative electrode terminal case 2a as in FIG. 14. In place of the insulating adhesive 7 illustrated in FIG. 14, a projection part 24 of the positive and negative electrode terminal case 2a is provided at a position opposite to the positive electrode part 11a on the top surface side of the cooling unit 5 as illustrated in FIG. 16. The projection part 24 may extend to the bottom surface of the sealing resin 10a. The projection part 24 contains the same material as that of the positive and negative electrode terminal case 2a and is formed integrally with the positive and negative electrode terminal case 2a. The projection part 24 can ensure the insulation distance between the positive electrode part 11a and the cooling unit 5.

Although not illustrated in the figure, the projection part 24 is also provided to extend at a position opposite to the negative electrode part 12a on the top surface side of the cooling unit 5. The projection part 24 can ensure the insulation distance between the negative electrode part 12a and the cooling unit 5.

Projection parts similar to the projection part 24 are also integrally formed in the positive and negative electrode terminal cases 2b, 2c and are also provided to extend at positions opposite to the positive electrode parts 11b, 11c and the negative electrode parts 12b, 12c, respectively, on the top surface side of the cooling unit 5. The projection parts can ensure the insulation distance between the positive electrode parts 11b, 11c and the negative electrode parts 12b, 12c, respectively, and the cooling unit 5.

The projection parts similar to the projection part 24 are also integrally provided in the output terminal cases 3a to 3c, and are also provided at positions opposite to the output parts 13a to 13c on the top surface side of the cooling unit 5. The projection parts can ensure the insulation distance between the output parts 13a to 13c and the cooling unit 5.

### Method for Manufacturing Semiconductor Device

One example of a method for manufacturing (method for assembling) the semiconductor device according to the first embodiment is described with reference to FIG. 17, for example. FIG. 17 is an exploded perspective view of the semiconductor device according to the first embodiment. FIG. 17 illustrates, as an example, a case in which the insulation sheet 7a is arranged in the connection portions between the semiconductor units 1a to 1c and the positive and negative electrode terminal cases 2a to 2c, respectively, and the insulation sheet 7b is arranged in the connection portions between the semiconductor units 1a to 1c and the output terminal cases 3a to 3c, respectively, as described in the modification of FIG. 15.

First, the semiconductor units 1a to 1c are prepared by transfer molding or the like which include the sealing resins 10a to 10c, the positive electrode parts 11a to 11c, the negative electrode parts 12a to 12c, and the output parts 13a to 13c protruding from the side surfaces of the sealing resins 10a to 10c, and the control units 14a to 14g exposed from the top surfaces of the sealing resin 10a to 10c, respectively. In addition, the control terminal units 4a to 4c are prepared by transfer molding or the like which include the control terminals (41a, 42a), (41b, 42b) (41c, 42c), (41d, 42d), (41e, 42e), (41f, 42f) (41f, 42f), (41g, 42g) and the terminal holding part 40 holding the control terminals (41a, 42a), (41b, 42b), (41c, 42c), (41d, 42d), (41e, 42e), (41f, 42f), (41g, 42g).

Next, the semiconductor units 1a to 1c, the positive and negative electrode terminal cases 2a to 2c, and the output terminal cases 3a to 3c are arranged, respectively, on the top surface side of the cooling unit 5 via the heat dissipation member 6 and the insulation sheets 7a, 7b. When the insulating adhesive 7 is used in place of the insulation sheets 7a, 7b, the insulating adhesive 7 is filled into the gaps between the positive electrode parts 11a to 11c, the negative electrode parts 12a to 12c, and the output parts 13a to 13c, respectively, and the cooling unit 5.

Next, the control terminal units 4a to 4c are arranged on the top surface sides of the semiconductor units 1a to 1c, respectively. The control units 14a to 14g of the semiconductor unit 1a and the control terminals (41a, 42a), (41b, 42b), (41c, 42c), (41d, 42d), (41e, 42e), (41f, 42f), (41g, 42g) of the control terminal unit 4a are bonded to each other, respectively, by laser welding or the like. The control units of the semiconductor units 1b, 1c and the control terminals of the control terminal units 4b, 4c are also bonded to each other, respectively, by laser welding or the like. Thus, the semiconductor device according to the first embodiment illustrated in FIGS. 1 to 4 is completed.

According to the semiconductor device of the first embodiment, the control units 14a to 14g are provided on the top surface sides of the semiconductor units 1a to 1c, respectively, and, separately from the semiconductor units 1a to 1c, the control terminal units 4a to 4c are provided which have the control terminals (41a, 42a), (41b, 42b), (41c, 42c), (41d, 42d), (41e, 42e), (41f, 42f), (41g, 42g) electrically connected to the control units 14a to 14g, respectively. This makes it possible to provide variations to the control terminals (41a, 42a), (41b, 42b), (41c, 42c), (41d, 42d), (41e, 42e), (41f, 42f), (41g, 42g) while maintaining the transfer moldability of the semiconductor units 1a to 1c. This makes it possible to meet various interface requirements without changing the semiconductor units 1a to 1c by preparing the control terminal units 4a to 4c meeting customer requests.

Further, according to the semiconductor device of the first embodiment, the positive and negative electrode terminal cases 2a to 2c are arranged between the positive electrode parts 11a to 11c and the negative electrode parts 12a to 12c, respectively, and the cooling unit 5 and the output terminal cases 3a to 3c are arranged between the output parts 13a to 13c, respectively, and the cooling unit 5. The insulating adhesives 7, 7x fill the regions (gaps) surrounded by the side surfaces of the sealing resins 10a to 10c, the positive electrode parts 11a to 11c, the negative electrode parts 12a to 12c, the output parts 13a to 13c, the positive and negative electrode terminal cases 2a to 2c, and the output terminal cases 3a to 3c of the semiconductor units 1a to 1c, respectively, so that the insulation distance can be ensured and the module size can be reduced. This makes it possible to meet various interface requirements without changing the semiconductor units 1a to 1c by preparing the positive and negative electrode terminal cases 2a to 2c and the output terminal cases 3a to 3c, respectively, meeting customer requests.

### Modification of First Embodiment

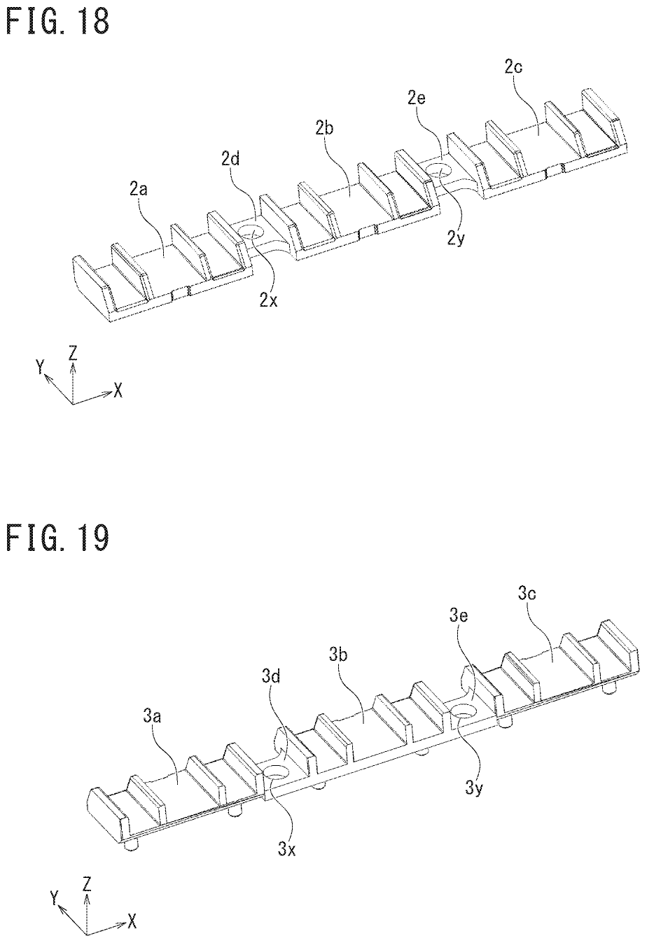

FIG. 18 is a perspective view of the positive and negative electrode terminal cases 2a to 2c of the semiconductor device according to the modification of the first embodiment. As illustrated in FIG. 18, the semiconductor device according to the modification of the first embodiment is different from the semiconductor device according to the first embodiment in that the positive and negative electrode terminal cases 2a to 2c are integrally formed via connection parts 2d, 2e. The connection parts 2d, 2e are provided with fastening holes (through holes) 2x, 2y capable of screw fastening.

FIG. 19 is a perspective view of the output terminal cases 3a to 3c of the semiconductor device according to the modification of the first embodiment. As illustrated in FIG. 19, the semiconductor device according to the modification of the first embodiment is different from the semiconductor device according to the first embodiment in that the output terminal cases 3a to 3c are integrally formed via connection parts 3d, 3e. The connection parts 3d, 3e are provided with fastening holes (through holes) 3x, 3y capable of screw fastening. The other configurations of the semiconductor device according to the modification of the first embodiment are substantially the same as those of the semiconductor device according to the first embodiment, and therefore duplicate descriptions are omitted.

According to the semiconductor device of the modification of the first embodiment, the positive and negative electrode terminal cases 2a to 2c and the output terminal cases 3a to 3c are integrally formed, respectively. This facilitates the assembly as compared with the case in which the positive and negative electrode terminal cases 2a to 2c and the output terminal cases 3a to 3c are divided. The control terminal units 4a to 4c may also be integrally formed instead of being separately formed.

### Second Embodiment

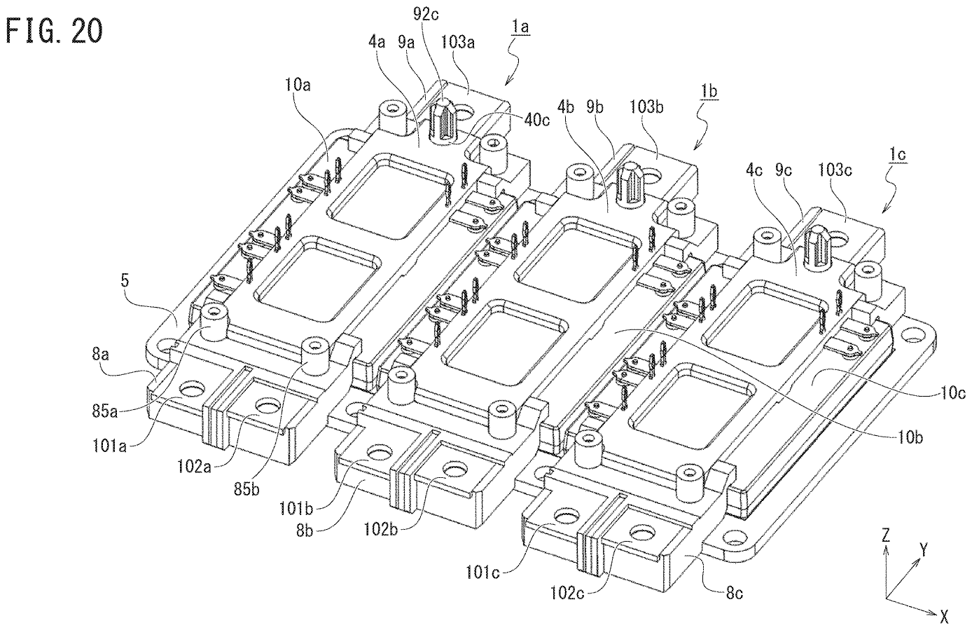

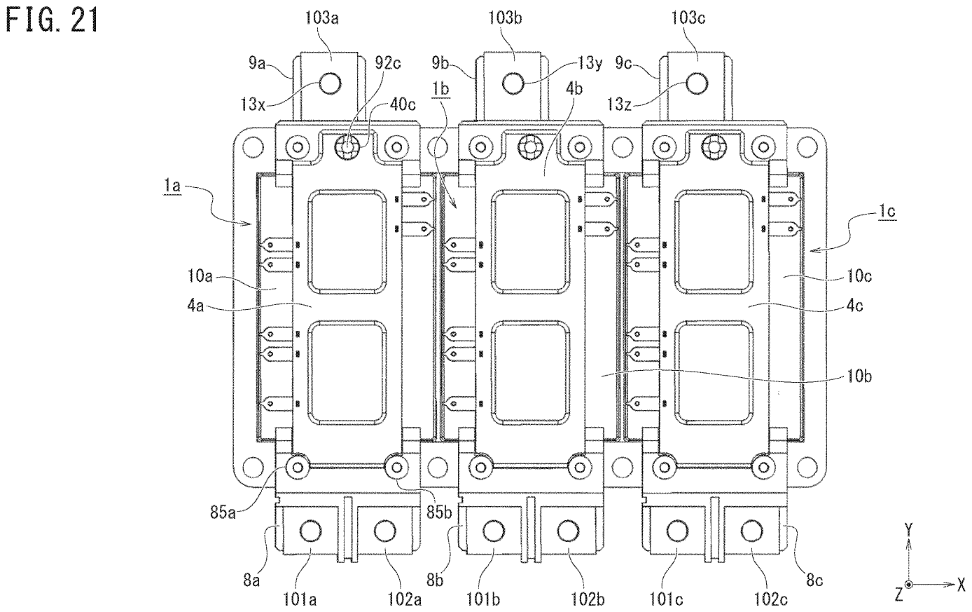

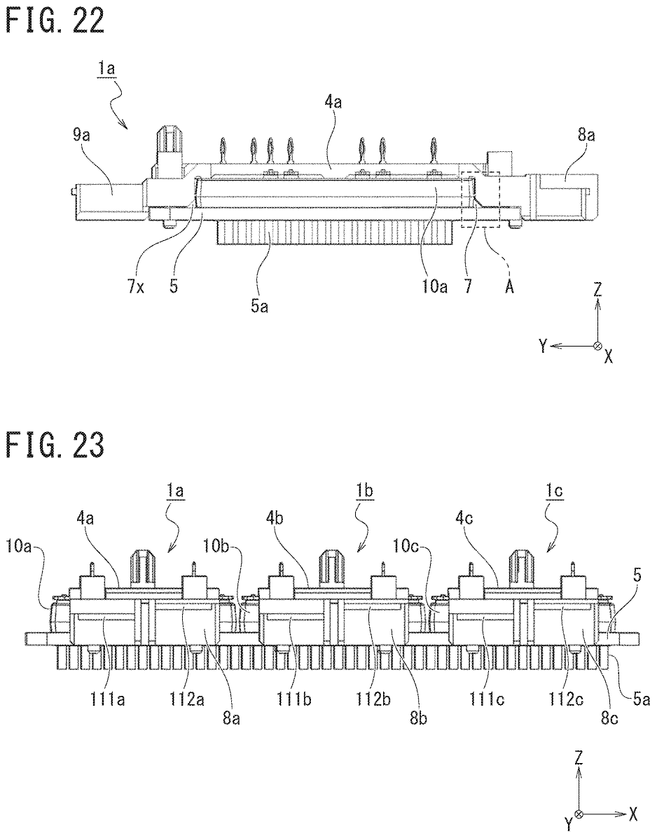

FIG. 20 is a perspective view of a semiconductor device according to a second embodiment. FIG. 21 is a top view of the semiconductor device according to the second embodiment. FIG. 22 is a side view of the semiconductor device according to the second embodiment as viewed in the positive direction of the X-axis direction. FIG. 23 is a side view of the semiconductor device according to the second embodiment as viewed in the positive direction of the Y-axis direction.

As illustrated in FIGS. 20 to 23, the semiconductor device according to the second embodiment includes the cooling unit 5, the semiconductor units 1a to 1c provided on the top surface side of the cooling unit 5, and the control terminal units 4a to 4c provided on the top surface sides of the semiconductor units 1a to 1c, respectively. In the semiconductor device according to the second embodiment, the configurations of the cooling unit 5 and the semiconductor units 1a to 1c are substantially the same as those of the cooling unit 5 and the semiconductor units 1a to 1c of the semiconductor device according to the first embodiment illustrated in FIGS. 1 to 6.

However, the semiconductor device according to the second embodiment is different from the semiconductor device according to the first embodiment illustrated in FIGS. 1 to 4 in that the semiconductor device according to the second embodiment further includes positive and negative electrode terminal units 8a to 8c containing positive electrode terminals 101a to 101c and negative electrode terminals 102a to 102c and output terminal units 9a to 9c containing output terminals 103a to 103c, respectively, and in the shapes of the plurality of control terminal units 4a to 4c.

As illustrated in FIGS. 20 to 23, the positive and negative electrode terminal unit 8a containing the positive electrode terminal 101a and the negative electrode terminal 102a and the output terminal unit 9a containing the output terminal 103a are provided to sandwich the semiconductor unit 1a in the direction orthogonal to the direction in which the semiconductor units 1a to 1c are aligned (Y-axis direction). The positive electrode terminal 101a is electrically connected to the positive electrode part 11a (see FIGS. 1 to 5) of the semiconductor unit 1a. The negative electrode terminal 102a is electrically connected to the negative electrode part 12a (see FIGS. 1 to 5) of the semiconductor unit 1a. The output terminal 103a is electrically connected to the output part 13a (see FIGS. 1 to 5) of the semiconductor unit 1a.

The positive and negative electrode terminal unit 8b containing the positive electrode terminal 101b and the negative electrode terminal 102b and the output terminal unit 9b containing the output terminal 103b are provided to sandwich the semiconductor unit 1b in the direction orthogonal to the direction in which the semiconductor units 1a to 1c are aligned (Y-axis direction). The positive electrode terminal 101b is electrically connected to the positive electrode part 11b (see FIGS. 1 to 4) of the semiconductor unit 1b. The negative electrode terminal 102b is electrically connected to the negative electrode part 12b (see FIGS. 1 to 4) of the semiconductor unit 1b. The output terminal 103b is electrically connected to the output part 13b (see FIGS. 1 to 4) of the semiconductor unit 1b.

The positive and negative electrode terminal unit 8c containing the positive electrode terminal 101c and the negative electrode terminal 102c and the output terminal unit 9c containing the output terminal 103c are provided to sandwich the semiconductor unit 1c in the direction orthogonal to the direction in which the semiconductor units 1a to 1c are aligned (Y-axis direction). The positive electrode terminal 101c is electrically connected to the positive electrode part 11c (see FIGS. 1 to 4) of the semiconductor unit 1c. The negative electrode terminal 102c is electrically connected to the negative electrode part 12c (see FIGS. 1 to 4) of the semiconductor unit 1c. The output terminal 103c is electrically connected to the output part 13c (see FIGS. 1 to 4) of the semiconductor unit 1c.

In the semiconductor device according to the second embodiment, the positive electrode terminals 101a to 101c, the negative electrode terminals 102a to 102c, and the output terminals 103a to 103c, respectively, constitute external connection terminals connectable to an external member in place of the positive electrode parts 11a to 11c, the negative electrode parts 12a to 12c, and the output parts 13a to 13c of the semiconductor units 1a to 1c, respectively.

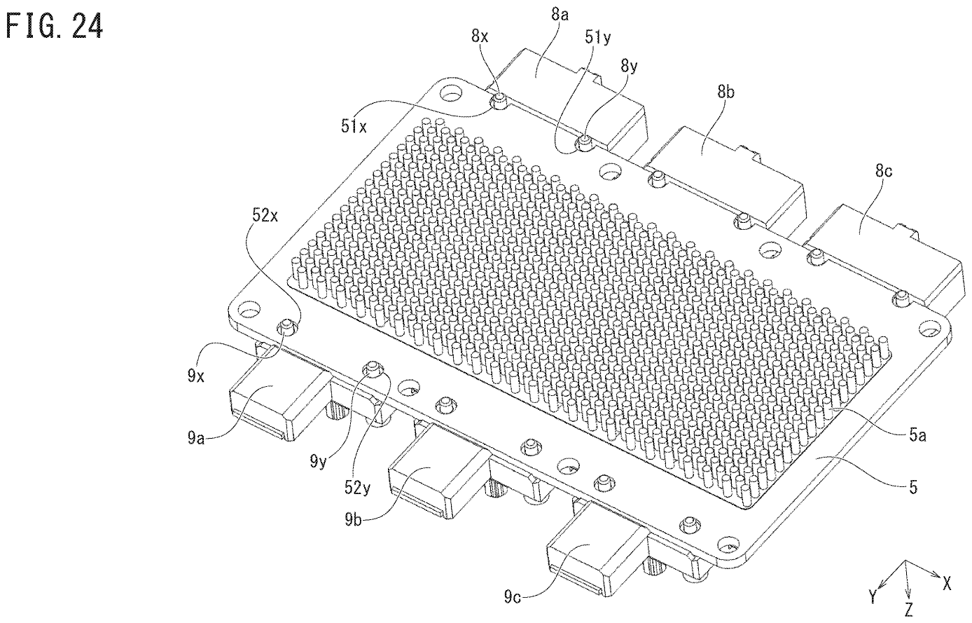

FIG. 24 is a perspective view viewed from the bottom surface side of the semiconductor device according to the second embodiment. As illustrated in FIG. 24, the positive and negative electrode terminal unit 8a includes protruding parts 8x, 8y engaged in (fitted into) recessed parts 51x, 51y of the cooling unit 5. The positive and negative electrode terminal units 8b, 8c also have the same configuration as that of the positive and negative electrode terminal unit 8a. The output terminal unit 9a has protruding parts 9x, 9y engaged in (fitted into) holes 52x, 52y of the cooling unit 5. The output terminal units 9b, 9c also have the same configuration as that of the output terminal unit 9a.

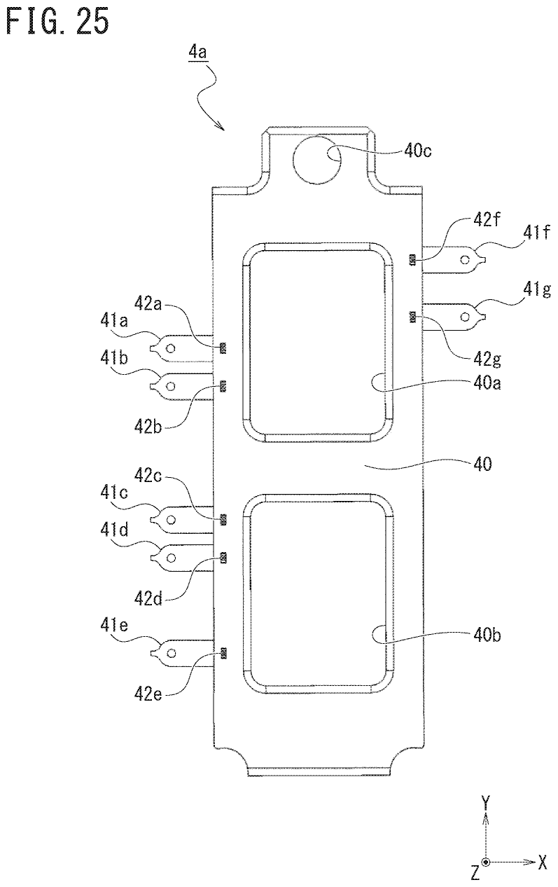

FIG. 25 is a top view of the control terminal unit 4a of the semiconductor device according to the second embodiment. The configurations of the terminal holding part 40 and the control terminals (41a, 42a), (41b, 42b), (41c, 42c), (41d, 42d), (41e, 42e), (41f, 42f), (41g, 42g) of the control terminal unit 4a are the same as those of the semiconductor device according to the first embodiment. The semiconductor device according to the second embodiment is different from the semiconductor device according to the first embodiment in that the control terminal unit 4a is provided with a hole 40c. As illustrated in FIGS. 20 and 21, when the control terminal unit 4a and the semiconductor unit 1a are assembled together, the hole 40c of the control terminal unit 4a is engaged in (fitted into) the protruding part 92c of the output terminal unit 9a, facilitating the assembly.

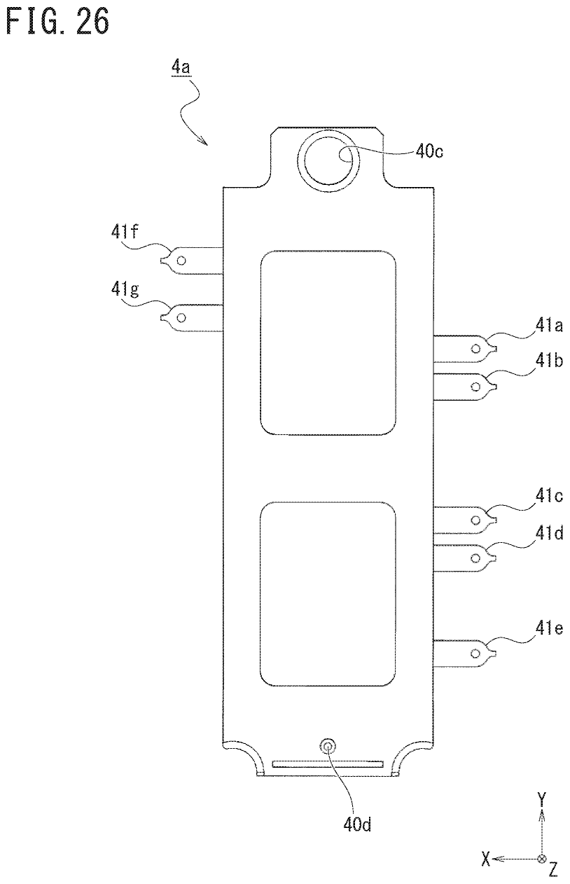

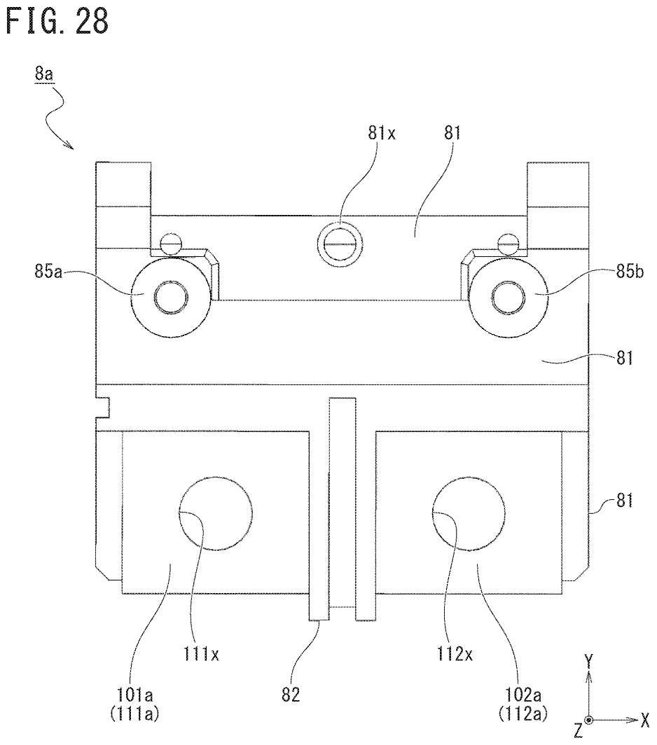

FIG. 26 is a bottom view of the control terminal unit 4a of the semiconductor device according to the second embodiment. The semiconductor device according to the second embodiment is different from the semiconductor device according to the first embodiment in that the control terminal unit 4a is provided with a protruding part 40d. When the control terminal unit 4a and the positive and negative electrode terminal unit 8a are assembled together, the protruding part 40d of the control terminal unit 4a is engaged in (fitted into) a hole 81x (see FIG. 28) of the positive and negative electrode terminal unit 8a, facilitating the assembly. The control terminal units 4b, 4c also have the same configuration as that of the control terminal unit 4a illustrated in FIGS. 25 and 26.

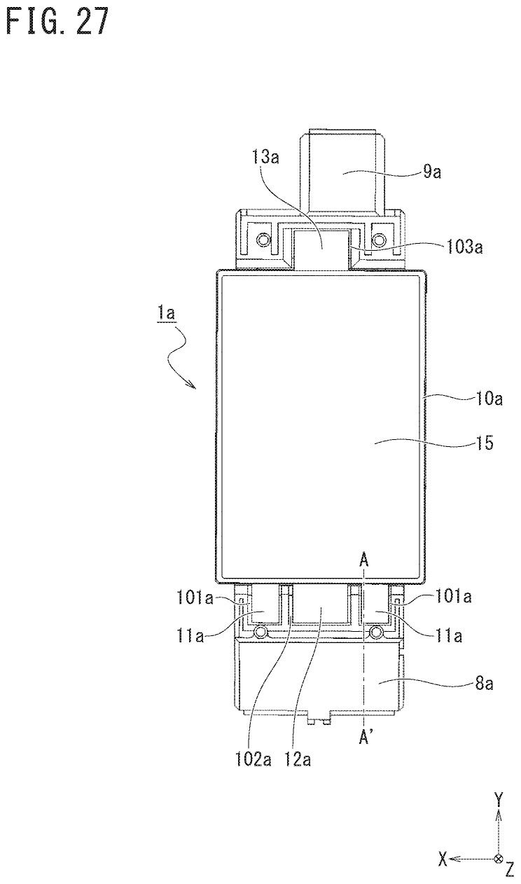

FIG. 27 is a bottom view of the semiconductor unit 1a, the positive and negative electrode terminal unit 8a, and the output terminal unit 9a. The pair of positive electrode parts 11a of the semiconductor unit 1a is bonded to the positive electrode terminals 101a exposed on the bottom surface side of the positive and negative electrode terminal unit 8a by laser welding or the like from the bottom surface side. The negative electrode part 12a of the semiconductor unit 1a is bonded to the negative electrode terminal 102a exposed on the bottom surface side of the positive and negative electrode terminal unit 8a by laser welding or the like from the bottom surface side. The output part 13a of the semiconductor unit 1a is bonded to the output terminal 103a exposed on the bottom surface side of the output terminal unit 9a by laser welding or the like from the bottom surface side.

The connection portions of the semiconductor unit 1b, the positive and negative electrode terminal unit 8b, and the output terminal unit 9b illustrated in FIGS. 20 to 23 and the connection portions of the semiconductor unit 1c, the positive and negative electrode terminal unit 8c, and the output terminal unit 9c illustrated in FIGS. 20 to 23 also have the same configuration as those of the connection portions of the semiconductor unit 1a, the positive and negative electrode terminal unit 8a, and the output terminal unit 9a illustrated in FIG. 27.

FIG. 28 is a top view of the positive and negative electrode terminal unit 8a. The positive and negative electrode terminal unit 8a includes the positive electrode terminal 101a and the negative electrode terminal 102a and a holding part 81 which is a resin member (insulation member) holding the positive electrode terminal 101a and the negative electrode terminal 102a.

The positive electrode terminal 101a and the negative electrode terminal 102a contain a conductive material, such as copper (Cu), a Cu alloy, aluminum (Al), or an Al alloy, for example. An exposed end part (terminal part) 111a which is a part of the positive electrode terminal 101a and an exposed end part (terminal part) 112a which is a part of the negative electrode terminal 102a are exposed from the holding part 81. The terminal part 111a of the positive electrode terminal 101a is provided with a fastening hole (through hole) 111x which allows screw fastening to an external member. The terminal part 112a of the negative electrode terminal 102a is provided with a fastening hole (through hole) 112x which allows screw fastening to an external member. When the positive electrode terminal 101a and the negative electrode terminal 102a are bonded to an external member by laser welding or the like, the positive electrode terminal 101a and the negative electrode terminal 102a do not have to be provided with the fastening holes.

The holding part 81 contains a resin material, such as polyphenylene sulfide (PPS), for example. The holding part 81 is provided with the hole 81x. The hole 81x is engaged in (fitted into) the protruding part 40d of the control terminal unit 4a illustrated in FIG. 26, facilitating the assembly. Between the terminal part 111a of the positive electrode terminal 101a and the terminal part 112a of the negative electrode terminal 102a of the holding part 81, a wall 82 is provided. The wall 82 ensures the insulation distance between the terminal part 111a of the positive electrode terminal 101a and the terminal part 112a of the negative electrode terminal 102a. The holding part 81 is provided with protruding parts 85a, 85b. The protruding parts 85a, 85b are positioned with the control terminal unit 4a as illustrated in FIGS. 20 and 21.

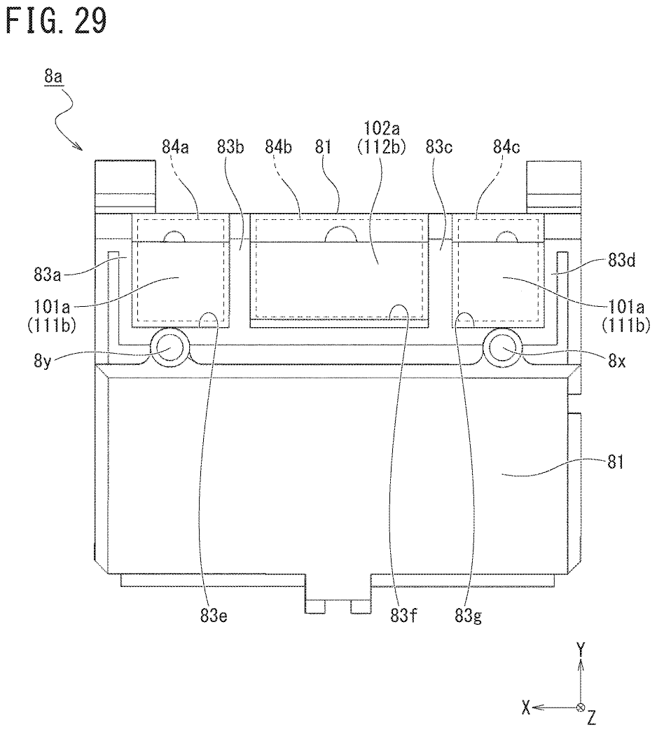

FIG. 29 is a bottom view of the positive and negative electrode terminal unit 8a. The holding part 81 is provided with walls 83a to 83d on the bottom surface side. Between the walls 83a, 83b, one of a pair of bonding parts 111b which is a part of the positive electrode terminal 101a is exposed. The walls 83a, 83b and a wall 83e of the holding part 81 connecting the walls 83a, 83b extend downward relative to one of the pair of bonding parts 111b. A space (recessed part) 84a is formed on the bottom surface side of the one of the pair of bonding parts 111b surrounded on three sides by the walls 83a, 83b, 83e. The one of the pair of bonding parts 111b has a portion connected to one of the pair of positive electrode parts 11a. When the one of the pair of bonding parts 111b and the one of the pair of positive electrode parts 11a are bonded by laser welding, the one of the pair of bonding parts 111b has a portion fusion-bonded to the one of the pair of positive electrode parts 11a.

Between the walls 83b, 83c, a bonding part 112b which is a part of the negative electrode terminal 102a is exposed. The walls 83c, 83b and a wall 83f of the holding part 81 connecting the walls 83b, 83c extend downward relative to the bonding part 112b. A space (recessed part) 84b is formed on the bottom surface side of the bonding part 112b surrounded on three sides by the walls 83b, 83c, 83f. The bonding part 112b has a portion connected to the negative electrode part 12a. When the bonding part 112b and the negative electrode part 12a are bonded by laser welding, the bonding part 112b has a portion fusion-bonded to the negative electrode part 12a.

Between the walls 83c, 83d, the other one of the pair of bonding parts 111b which is part of the positive electrode terminal 101a is exposed. The walls 83c, 83d and a wall 83g of the holding part 81 connecting the walls 83c, 83d extend downward relative to the other one of the pair of bonding parts 111b. A space (recessed part) 84c is formed on the bottom surface side of the other one of the pair of bonding parts 111b surrounded on three sides by the walls 83c, 83d, 83g. The other one of the pair of bonding parts 111b has a portion connected to the other one of the pair of positive electrode parts 11a. When the other one of the pair of bonding parts 111b and the other one of the pair of positive electrode parts 11a are bonded by laser welding, the other one of the pair of bonding parts 111b has a portion fusion-bonded to the other one of the pair of positive electrode parts 11a.

The bonding part 112b is positioned between the pair of bonding parts 111b. The wall 83b ensures the insulation distance between one of the pair of bonding parts 111b and the bonding part 112b. The wall 83c ensures the insulation distance between the bonding part 112b and the other one of the pair of bonding parts 111b.

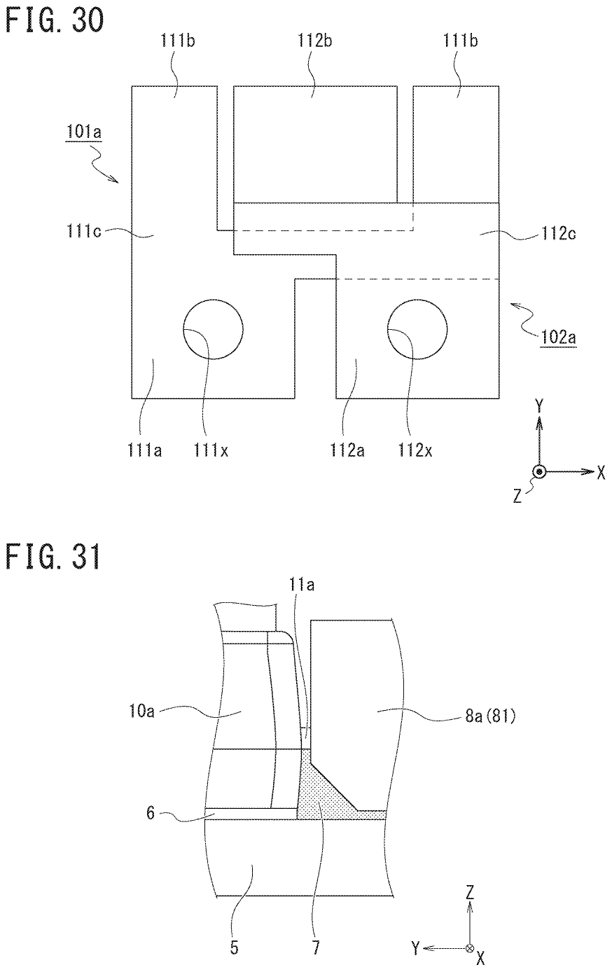

FIG. 30 is a top view of only the positive electrode terminal 101a and the negative electrode terminal 102a, in which the holding part 81 of the positive and negative electrode terminal unit 8a is not illustrated. The positive electrode terminal 101a includes the terminal part 111a exposed from the top surface side of the holding part 81, the intermediate part 111c connected to the terminal part 111a and provided inside the holding part 81, and the pair of bonding parts 111b connected to the intermediate part 111c and exposed from the bottom surface side of the holding part 81. The negative electrode terminal 102a includes the terminal part 112a exposed from the top surface side of the holding part 81, the intermediate part 112c connected to the terminal part 112a, provided inside the holding part 81, and having a bent portion, and the bonding part 112b connected to the intermediate part 112c and exposed from the bottom surface side of the holding part 81. In plan view, the intermediate part 112c of the negative electrode terminal 102a has a region in which the main surface overlaps (intersects) the intermediate part 111c of the positive electrode terminal 101a.

FIG. 31 is a side view of a connection portion between the semiconductor unit 1a and the positive and negative electrode terminal unit 8a, in which a dashed-line region A illustrated in FIG. 22 is enlarged. As illustrated in FIG. 31, the insulating adhesive 7 is filled into the space surrounded by the top surface of the cooling unit 5, the heat dissipation member 6, the sealing resin 10a, one of the pair of positive electrode parts 11a, and the positive and negative electrode terminal unit 8a to attach the members to each other. The insulating adhesive 7 covers a region facing at least the positive electrode part 11a and the negative electrode part 12a of the top surface of the cooling unit 5 in plan view. As the insulating adhesive 7, an epoxy resin adhesive or the like can be used. The insulating adhesive 7 has viscosity of about 5000 mPa·s (25 °C) or more.

Although not illustrated in the figure, the insulating adhesive 7 is also filled into the space surrounded by the top surface of the cooling unit 5, the heat dissipation member 6, the sealing resin 10a, the other one of the pair of positive electrode parts 11a, and the positive and negative electrode terminal unit 8a to attach the members to each other. The insulating adhesive 7 is also filled into the space surrounded by the top surface of the cooling unit 5, the heat dissipation member 6, the sealing resin 10a, the negative electrode part 12a, and the positive and negative electrode terminal unit 8a to attach the members to each other.

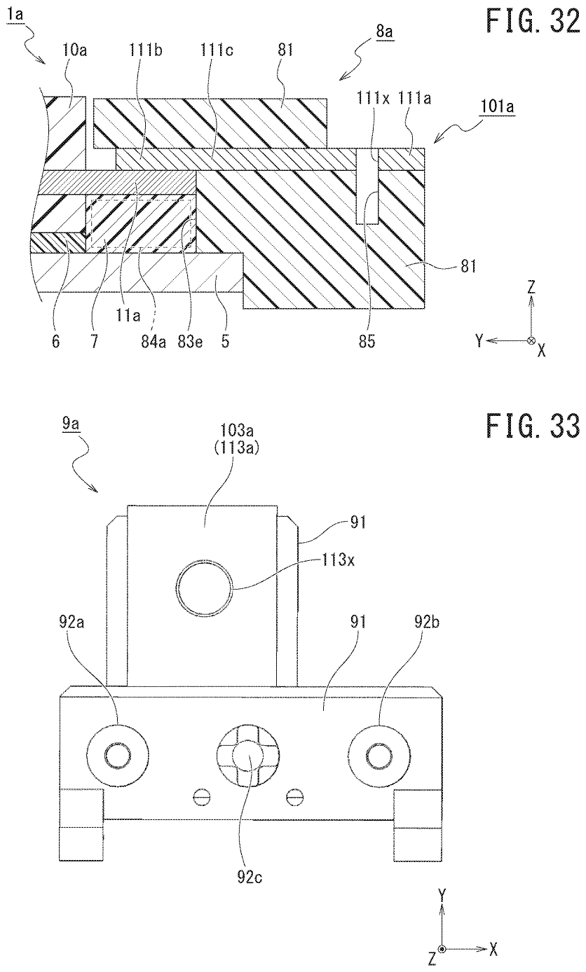

FIG. 32 is a cross-sectional view of the connection portion between the semiconductor unit 1a and the positive and negative electrode terminal unit 8a, corresponding to the position of the A-A′ line of FIG. 27. As illustrated in FIG. 32, one of the pair of bonding parts 111b of the positive electrode terminal 101a and one of the pair of positive electrode parts 11a of the semiconductor unit 1a are bonded by laser welding or the like from the bottom surface side. The insulating adhesive 7 is filled into the space (recessed part) 84a surrounded by the top surface of the cooling unit 5, the side surface of the sealing resin 10a of the semiconductor unit 1a, the bottom surface of the one of the pair of positive electrode parts 11a, and the walls 83a, 83b, 83e of the holding part 81 to attach the members to each other. The insulating adhesive 7 can ensure the insulation distance between the one of the pair of positive electrode parts 11a and the cooling unit 5.

Although not illustrated in the figure, the other one of the pair of bonding parts 111b of the positive electrode terminal 101a and the other one of the pair of positive electrode parts 11a of the semiconductor unit 1a are bonded by laser welding or the like. The insulating adhesive 7 is filled into the space (recessed part) 84c surrounded by the top surface of the cooling unit 5, the side surface of the sealing resin 10a of the semiconductor unit 1a, the bottom surface of the other one of the pair of positive electrode parts 11a, and the walls 83c, 83d, 83g of the holding part 81 to attach the members to each other. The insulating adhesive 7 can ensure the insulation distance between the other one of the pair of positive electrode parts 11a and the cooling unit 5.

The bonding part 112b of the negative electrode terminal 102a and the negative electrode part 12a of the semiconductor unit 1a are bonded by laser welding or the like. The insulating adhesive 7 is filled into the space (recessed part) 84b surrounded by the top surface of the cooling unit 5, the side surface of the sealing resin 10a of the semiconductor unit 1a, the bottom surface of the negative electrode part 12a, and the walls 83b, 83c, 83f of the holding part 81 to attach the members to each other. The insulating adhesive 7 can ensure the insulation distance between the negative electrode part 12a and the cooling unit 5. Connection portions between the semiconductor units 1b, 1c and the positive and negative electrode terminal units 8b, 8c, respectively, also have the same configuration as that of the connection portion between the semiconductor unit 1a and the positive and negative electrode terminal unit 8a.

In the semiconductor device according to the second embodiment, an insulation sheet may be provided on the top surface side of the cooling unit 5 in place of the insulating adhesive 7 illustrated in FIGS. 31 and 32. The insulation sheet covers a region facing at least the positive electrode parts 11a to 11c, the negative electrode parts 12a to 12c, and the output parts 13a to 13c, respectively, of the top surface of the cooling unit 5 in plan view. The insulation sheet further extends to the bottom surfaces of the outer edges of the semiconductor units 1a to 1c, the bottom surface sides of the positive and negative electrode terminal units 8a to 8c, and the bottom surfaces of the output terminal units 9a to 9c, respectively. The insulation sheet can ensure the insulation distance of the pair of positive electrode parts 11a to 11c and the negative electrode parts 12a to 12c, respectively, and the cooling unit 5.

FIG. 33 is a top view of the output terminal unit 9a. The output terminal unit 9a includes the output terminal 103a and a holding part 91 holding the output terminal 103a. The output terminal 103a contains a conductive material, such as copper (Cu), a Cu alloy, aluminum (Al), or an Al alloy, for example. An exposed end part (terminal part) 113a which is a part of the output terminal 103a is exposed from the holding part 91. The terminal part 113a of the output terminal 103a is provided with a fastening hole (through hole) 113x which allows screw fastening to an external member.

The holding part 91 contains a resin material, such as polyphenylene sulfide (PPS), for example. The holding part 91 is provided with protruding parts 92a to 92c on the top surface side. The protruding part 92c is engaged in (fitted into) the hole 40c of the control terminal unit 4a illustrated in FIGS. 25 and 26, facilitating the assembly.

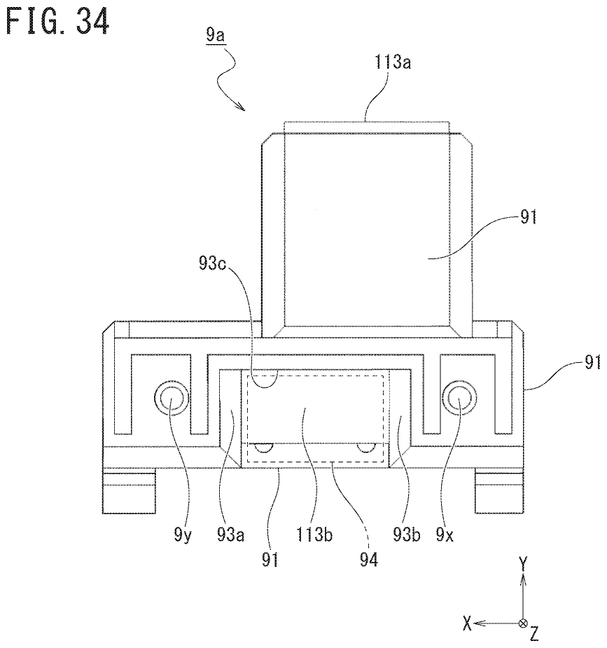

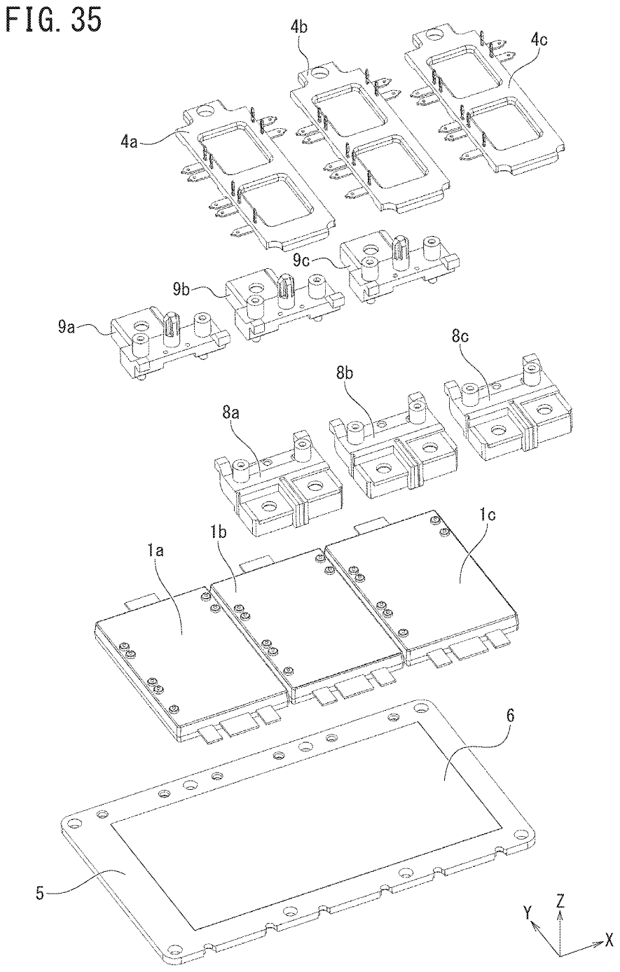

FIG. 34 is a bottom view of the output terminal unit 9a. The holding part 91 is provided with protruding parts 9x, 9y on the bottom surface side. The protruding parts 9x, 9y are engaged in (fitted into) holes 52x, 52y of the cooling unit 5 as illustrated in FIG. 24, facilitating the assembly. On the bottom surface side of the holding part 91, a bonding part 113b which is a part of the output terminal 103a is exposed. Although not illustrated in the figure, the output terminal 103a includes the terminal part 113a exposed from the top surface side of the holding part 91, an intermediate part connected to the terminal part 113a and provided inside the holding part 91, and the bonding part 113b connected to the intermediate part and exposed from the bottom surface side of the holding part 91. Around the bonding part 113b, walls 93a to 93c of the holding part 91 extend downward relative to the bonding part 113b. A space (recessed part) 94 surrounded on three sides by the walls 93a to 93c is formed.

On the bottom surface side of the bonding part 113b, the output part 13a of the semiconductor unit 1a is stacked and bonded by laser welding or the like. The insulating adhesive 7x similar to the insulating adhesive 7 (see FIG. 22) is filled into the space 94 surrounded by the side surface of the sealing resin 10a of the semiconductor unit 1a, the bottom surface of the output part 13a, the top surface of the cooling unit 5, and the walls 93a to 93c of the holding part 91 to attach the members to each other. The insulating adhesive 7x covers a region facing at least the output part 13a of the top surface of the cooling unit 5 in plan view. The insulating adhesive 7x can ensure the insulation distance between the output part 13a and the cooling unit 5. Connection portions between the semiconductor units 1b, 1c and the output terminal units 9b, 9c, respectively, also have the same configuration as that of the connection portion between the semiconductor unit 1a and the output terminal unit 9a.

The other configurations of the semiconductor device according to the second embodiment are substantially the same as those of the semiconductor device according to the first embodiment, and therefore duplicate descriptions are omitted.

### Method for Manufacturing Semiconductor Device

One example of a method for manufacturing (method for assembling) the semiconductor device according to the second embodiment is described with reference to FIG. 35. FIG. 35 is an exploded perspective view of the semiconductor device according to the second embodiment.

First, the semiconductor units 1a to 1c are prepared by transfer molding or the like which include the sealing resins 10a to 10c, the positive electrode parts 11a to 11c, the negative electrode parts 12a to 12c, and the output parts 13a to 13c protruding from the side surfaces of the sealing resins 10a to 10c, and the control units 14a to 14g exposed from the top surfaces of the sealing resin 10a to 10c, respectively. In addition, the control terminal units 4a to 4c are prepared by transfer molding or the like which include the control terminals (41a, 42a), (41b, 42b) (41c, 42c), (41d, 42d), (41e, 42e), (41f, 42f) (41f, 42f), (41g, 42g) and the terminal holding part 40 holding the control terminals (41a, 42a), (41b, 42b), (41c, 42c), (41d, 42d), (41e, 42e), (41f, 42f), (41g, 42g).

In addition, the positive and negative electrode terminal units 8a to 8c are prepared by transfer molding or the like which include the positive electrode terminals 101a to 101c, the negative electrode terminals 102a to 102c, and the holding part 81 holding the positive electrode terminals 101a to 101c and the negative electrode terminals 102a to 102c, respectively. In addition, the output terminal units 9a to 9c are prepared by transfer molding or the like which include the output terminals 103a to 103c and the holding part 91 holding the output terminals 103a to 103c, respectively.

Next, the top surfaces of the positive electrode part 11a and the negative electrode part 12a of the semiconductor unit 1a are individually stacked on the bottom surfaces of the bonding part 111b of the positive electrode terminal 101a and the bonding part 112b of the negative electrode terminal 102a exposed on the bottom surface side of the positive and negative electrode terminal unit 8a, and bonded by laser welding or the like from the bottom surface side. Then, the insulating adhesive 7 is filled into the spaces 84a to 84c on the bottom surface sides of the positive electrode part 11a and the negative electrode part 12a of the semiconductor unit 1a. The connections between the positive and negative electrode terminal units 8b, 8c and the semiconductor units 1b, 1c, respectively, are made in the same manner.

Next, the top surface of the output part 13a of the semiconductor unit 1a is stacked on the bottom surface of the bonding part 113b of the output terminal 103a exposed on the bottom surface side of the output terminal unit 9a, and bonded by laser welding or the like from the bottom surface side. Then, the insulating adhesive 7x is filled into the space 94 on the bottom surface side of the output part 13a of the semiconductor unit 1a. The connections between the output terminal units 9b, 9c and the semiconductor units 1b, 1c, respectively, are made in the same manner.

Next, a work in which the semiconductor units 1a to 1c, the positive and negative electrode terminal units 8a to 8c, respectively, and the output terminal units 9a to 9c are integrated is arranged on the top surface side of the cooling unit 5 via the heat dissipation member 6. At this time, the spaces between the top surface of the cooling unit 5 and the positive electrode parts 11a to 11c, the negative electrode parts 12a to 12c, and the output parts 13a to 13c of the semiconductor units 1a to 1c are attached to each other, respectively, by the insulating adhesives 7, 7x, and the insulation distance is ensured.

Next, the control terminal units 4a to 4c are arranged on the top surface sides of the semiconductor units 1a to 1c, respectively. The control units 14a to 14g of the semiconductor unit 1a and the control terminals (41a, 42a), (41b, 42b), (41c, 42c), (41d, 42d), (41e, 42e), (41f, 42f), (41g, 42g) of the control terminal unit 4a are bonded by laser welding or the like. The control units and the control terminals of the control terminal units 4b, 4c of the semiconductor units 1b, 1c, respectively, are also bonded by laser welding or the like. Thus, the semiconductor device according to the second embodiment illustrated in FIGS. 20 to 24 is completed.

According to the semiconductor device of the second embodiment, the control units 14a to 14g are provided on the top surface sides of the semiconductor units 1a to 1c, respectively, and, separately from the semiconductor units 1a to 1c, the control terminal units 4a to 4c are provided which have the control terminals (41a, 42a), (41b, 42b), (41c, 42c), (41d, 42d), (41e, 42e), (41f, 42f), (41g, 42g) electrically connected to the control units 14a to 14g. This makes it possible to provide variations to the control terminals (41a, 42a), (41b, 42b), (41c, 42c), (41d, 42d), (41e, 42e), (41f, 42f), (41g, 42g) while maintaining the transfer moldability of the semiconductor units 1a to 1c. This makes it possible to meet various interface requirements.

Further, according to the semiconductor device of the second embodiment, the positive and negative electrode terminal units 8a to 8c and the output terminal units 9a to 9c are prepared in place of the positive and negative electrode terminal cases 2a to 2c and the output terminal cases 3a to 3c, respectively, used in the semiconductor device of the first embodiment. Then, the positive and negative electrode terminal units 8a to 8c are electrically connected to the positive electrode parts 11a to 11c and the negative electrode parts 12a to 12c of the semiconductor units 1a to 1c, respectively, and the output terminal units 9a to 9c are electrically connected to the output parts 13a to 13c of the semiconductor units 1a to 1c, respectively, so that an external member can be fastened, with screws, to the positive electrode terminals 101a to 101c, the negative electrode terminals 102a to 102c, and the output terminals 103a to 103c, respectively. This makes it possible to meet various interface requirements without changing the semiconductor units 1a to 1c.

Further, according to the semiconductor device of the second embodiment, the insulating adhesive 7 or the like fills the spaces 84a to 84c, 94 surrounded by the side surfaces of the sealing resins 10a to 10c of the semiconductor units 1a to 1c, respectively, the bottom surfaces of the positive electrode parts 11a to 11c, the negative electrode parts 12a to 12c, and the output parts 13a to 13c of the semiconductor units 1a to 1c, respectively, and the top surface of the cooling unit 5, so that the insulation distance between the positive electrode parts 11a to 11c, the negative electrode parts 12a to 12c, and the output parts 13a to 13c, respectively, and the cooling unit 5 can be ensured. Further, the attachment area by the insulating adhesive 7 is small, and therefore thermal stress in operation or in the operating environment of the semiconductor device according to the second embodiment is small, and thus the occurrence of peeling of the parts attached to each other by the insulating adhesive 7 can be reduced.

Further, according to the semiconductor device of the second embodiment, the positive electrode parts 11a to 11c, the negative electrode parts 12a to 12c, and the output parts 13a to 13c of the semiconductor units 1a to 1c and the positive electrode terminals 101a to 101c, the negative electrode terminals 102a to 102c, and the output terminals 103a to 103c are bonded to each other by laser welding from the bottom surface side, outside the sealing resins 10a to 10c of the semiconductor units 1a to 1c, respectively. This prevents spatter in welding from scattering onto the internal circuits of the semiconductor units 1a to 1c and allows the positive electrode terminals 101a to 101c, the negative electrode terminals 102a to 102c, and the output terminals 103a to 103c to be bonded to the semiconductor units 1a to 1c, respectively.

### Modification of Second Embodiment

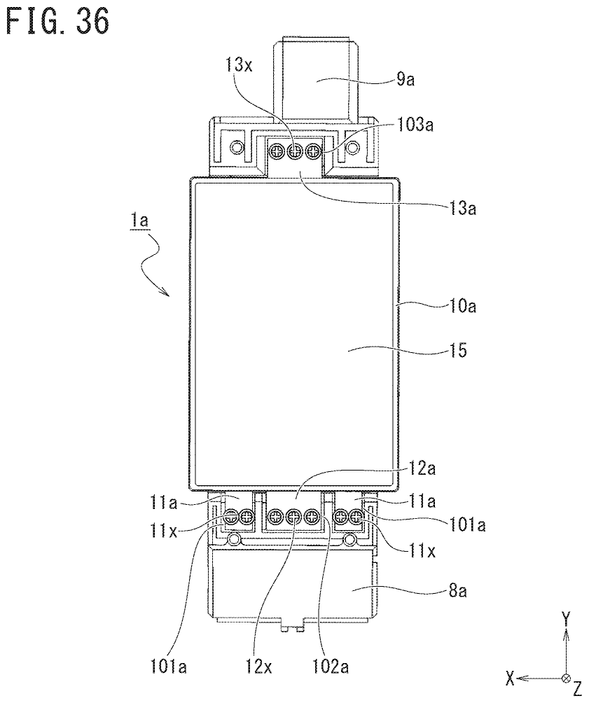

FIG. 36 is a bottom view of the semiconductor unit 1a, the positive and negative electrode terminal unit 8a, and the output terminal unit 9a of a semiconductor device according to a modification of the second embodiment. The semiconductor device according to the modification of the second embodiment is different from the semiconductor device according to the second embodiment in that the pair of positive electrode parts 11a and the negative electrode part 12a of the semiconductor unit 1a are fastened (connected) to the positive electrode terminals 101a and the negative electrode terminal 102a of the positive and negative electrode terminal unit 8a with screws 11x, 12x, respectively, in place of being bonded by laser welding and that the output part 13a of the semiconductor unit 1a is fastened (connected) to the output terminal 103a of the output terminal unit 9a with screws 13x in place of being bonded by laser welding. The other configurations of the semiconductor device according to the modification of the second embodiment are substantially the same as those of the semiconductor device according to the second embodiment, and therefore duplicate descriptions are omitted.

### Other Embodiments

The first and second embodiments of the present disclosure have been described above, but it should be understood that the description and the drawings as part of the present disclosure do not restrict the present disclosure. Various alternative embodiments, examples, and operational technologies will become clear to a person skilled in the art from the present disclosure.

For example, in the first and second embodiments, the pairs of positive electrode parts 11a to 11c and the negative electrode parts 12a to 12c of the semiconductor units 1a to 1c, respectively, may be configured in the reverse manner. More specifically, the semiconductor units 1a to 1c may include a pair of negative electrode parts and one positive electrode part sandwiched between the pair of negative electrode parts. Further, in the second embodiment, the positive electrode terminals 101a to 101c and the negative electrode terminals 102a to 102c held by the positive and negative electrode terminal units 8a to 8c, respectively, may be configured in the reverse manner.

The configurations disclosed in the first and second embodiments can be combined appropriately as far as no consistency occurs. It is needless to say that the present disclosure includes various embodiments and so on that are not described herein. Accordingly, the technical scope of the present disclosure is determined only by the invention specification matter according to appropriate claims from the above description.

1. A semiconductor device comprising:
a semiconductor unit having a sealing resin configured to seal a semiconductor chip, a positive electrode part and a negative electrode part extending from one side surface of the sealing resin, an output part extending from another side surface opposite to the one side surface, and a plurality of control units exposed from the sealing resin;
a first resin member arranged opposite to the one side surface and having an insulating first wall arranged between the positive electrode part and the negative electrode part;
a second resin member arranged opposite to the other side surface; and
a third resin member configured to hold a plurality of control terminals respectively bonded to the control units.

2. The semiconductor device according to claim 1, further comprising:
a cooling unit arranged on a bottom surface side of the semiconductor unit, wherein
an insulation sheet is provided, the insulation sheet being configured to cover a region facing at least the positive electrode part, the negative electrode part, and the output part of a top surface of the cooling unit in plan view and extending to a bottom surface of an outer edge of the semiconductor unit, a bottom surface side of the first resin member, and a bottom surface of the second resin member.

3. The semiconductor device according to claim 1, wherein the third resin member is arranged on the semiconductor unit and engaged with the first resin member and the second resin member.

4. The semiconductor device according to claim 1, wherein one end of the control terminal extends in a side surface direction of the third resin member.

5. The semiconductor device according to claim 1, wherein
in the semiconductor unit, one of the positive electrode part or the negative electrode part has a width larger in a direction orthogonal to an extension direction of the positive electrode part and the negative electrode part than a width of another one of the positive electrode part or the negative electrode part,
the output part of the semiconductor unit has a width in a direction orthogonal to an extension direction of the output part same as the width of one of the positive electrode part or the negative electrode part, and
the second resin member has a shape same as a shape of the first resin member.

6. The semiconductor device according to claim 1,
the semiconductor unit having a plurality of the positive electrode parts,
the semiconductor device further comprising:
a positive electrode terminal held by the first resin member, having a fastening hole, and having a plurality of bonding parts connected to the positive electrode parts; and
a negative electrode terminal held by the first resin member, having a fastening hole, and having a bonding part connected to the negative electrode part, and
wherein the first resin member has a second wall configured to separate the positive electrode terminal and the negative electrode terminal from each other.

7. The semiconductor device according to claim 1, further comprising:
an output terminal held by the second resin member, having a fastening hole, and connected to the output part.

8. The semiconductor device according to claim 1, wherein the control unit includes a pin protruding from a top surface of the sealing resin.

9. The semiconductor device according to claim 1, wherein the control unit includes a pad flush with a top surface of the sealing resin.

10. The semiconductor device according to claim 2, comprising:
a plurality of the semiconductor units arranged on the cooling unit,
wherein
the first resin member corresponding to each of the semiconductor unit is integrally formed, and
the second resin member corresponding to each of the semiconductor unit is integrally formed.
